(19) United States
(12) Patent Application Publication
(10) Pub. No.: US 2026/0044080 A1
(43) Pub. Date: Feb. 12, 2026

(54) COPOLYMER, PHOTOSENSITIVE RESIN COMPOSITION, RESIN CURED FILM, AND IMAGE DISPLAY ELEMENT

(71) Applicant: RESONAC CORPORATION, Tokyo (JP)

(72) Inventors: Eri IDA, Tokyo (JP); Tomomitsu WAKABAYASHI, Tokyo (JP)

(73) Assignee: RESONAC CORPORATION, Tokyo (JP)

(21) Appl. No.: 19/166,962

(22) PCT Filed: Jun. 9, 2023
(86) PCT No.: PCT/JP2023/021538

§ 371 Date: Sep. 19, 2025

(30) Foreign Application Priority Data
Dec. 20, 2022 (JP) 2022-203091

(51) Int. Cl. G03F 7/038; C08F 220/06; C08F 220/18; C08F 220/20; C08F 220/36; C08F 220/40

(52) U.S. Cl. CPC G03F 7/038; C08F 220/06; C08F 220/1808; C08F 220/20; C08F 220/36; C08F 220/365; C08F 220/40; C08F 2800/10

(57) ABSTRACT

The copolymer has an acid group-bearing structural unit (a) and a structural unit (b) that has a group represented by formula (1-1) (In formula (1-1), R¹ is a hydrogen atom or a hydrocarbon group having 1-20 carbon atoms; R² and R³ are each independently a hydrogen atom or a hydrocarbon group having 1-20 carbon atoms; and * represents a linking site that links to a residue provided by the removal of the group with formula (1-1) from the structural unit (b).).

### TECHNICAL FIELD

The present invention relates to a copolymer, a photosensitive resin composition, a photosensitive coloring composition, a resin cured film, and an image display element.

### BACKGROUND ART

Recently, from the viewpoint of resource and energy saving, in the fields of various coatings, printing, paints, adhesives, and the like, photosensitive resin compositions that can be cured by active energy rays, such as ultraviolet rays and electron beams, have been in wide use. In the field of electronic materials such as printed circuit boards, photosensitive resin compositions that can be cured by active energy rays have been in use for solder resists, color filter resists, and the like. For curable photosensitive resin compositions, required characteristics are becoming more and more diverse and sophisticated; however, in particular, short-time curability in consideration of productivity and low-temperature curability curbing thermal damage to members to which compositions are to be applied are in demand.

A color filter is generally composed of a transparent substrate, such as a glass substrate, red (R), green (G), and blue (B) pixels formed on the transparent substrate, black matrices formed at the boundaries of the pixels, and a protective film formed on the pixels and the black matrices. The color filter having such a configuration is usually produced by sequentially forming the black matrices, the pixels, and the protective film on the transparent substrate. As a method for sequentially forming the pixels and the black matrices (hereinafter, the pixels and the black matrices will be referred to as “coloring patterns”), various methods have been proposed. Among them, a pigment/dye dispersion method in which a photosensitive resin composition is used as a resist and the coloring patterns are prepared by a photolithography method in which application, exposure, development, and baking are repeated imparts coloring patterns, which are excellent in terms of durability and have few defects, such as pin holes, and thus has become mainstream.

In general, the photosensitive resin composition used in the photolithography method contains an alkali-soluble resin, a reactive diluent, a photopolymerization initiator, a coloring agent, and a solvent. The pigment/dye dispersion method has the above-described advantages, but baking is repeated to form the black matrices and the R, G, and B patterns, and the photosensitive resin composition is thus required to be highly heat-resistant, and there is often a problem in that coloring agents that can be used are limited to coloring agents that can withstand high baking temperatures.

In recent years, there has been proposed a photosensitive resin composition having low-temperature curability that can also be applied to poorly heat-resistant members, such as organic EL. For example, PTL 1 discloses a coloring composition having a specific partial structure and a hydroxy group as a photosensitive resin composition that can impart a cured product having excellent solvent resistance even under low-temperature curing conditions and can be suitably used for applications such as color filters.

### CITATION LIST

### Patent Literature

PTL 1: Japanese Patent Application Publication No. 2021-102759

### SUMMARY OF INVENTION

### Technical Problem

However, in recent years, better low-temperature curability has been required, and accordingly, there has been a concern that films may not be sufficiently cured and solvent resistance may deteriorate as a trade-off. Therefore, prepared cured products are required to have high solvent resistance even in curing under low-temperature conditions. In addition, photosensitive resin compositions are required to have excellent developability.

The present invention has been made to solve the above-described problem, and an object of the present invention is to provide a copolymer that contributes to improvement in developability and imparts a resin cured film having excellent solvent resistance, and a photosensitive resin composition and a photosensitive coloring composition for which the copolymer is used. Another object of the present invention is to provide a resin cured film having excellent solvent resistance and an image display element comprising the resin cured film.

### Solution to Problem

The present invention includes the following aspects.

[1]

A copolymer comprising
a structural unit (a) having an acid group; and
a structural unit (b) having a group represented by the following formula (1-1) or the following formula (1-2):

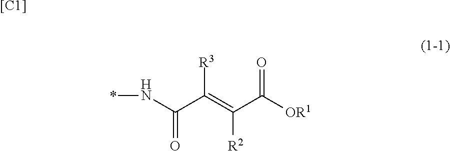

wherein, in formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group of formula (1-1) from the structural unit (b);

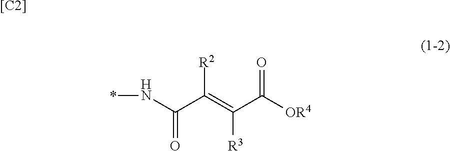

wherein, in formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group of formula (1-2) from the structural unit (b).
   [2]

The copolymer according to aspect [1], further comprising
a structural unit (c) having a hydroxy group; and
a structural unit (d) having a blocked isocyanate group.
   [3]

The copolymer according to aspect [2], wherein a blocking agent of the structural unit (d) having a blocked isocyanate group is one or more selected from the group consisting of 3,5-dimethylpyrazole, methyl ethyl ketoxime, methyl 4-hydroxybenzoate, methyl 2-hydroxybenzoate, and 3,5-xylenol.

[4]

The copolymer according to aspect [2], wherein the blocking agent of the structural unit (d) having a blocked isocyanate group has a carboxylic acid alkyl ester structure.

[5]

The copolymer according to aspect [2], wherein the structural unit (d) having a blocked isocyanate group has a group represented by the following formula (2) or a group represented by the following formula (3):

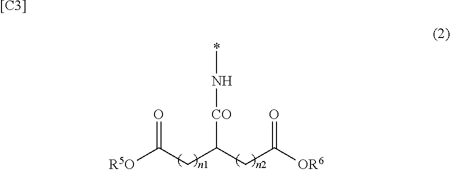

wherein, in formula (2), R⁵ and R⁶ each independently represent an alkyl group having 1 to 10 carbon atoms, n1 and n2 each independently represent an integer of 0 to 2, and * represents a linking site with a residue obtained by removing the blocked isocyanate group from the structural unit (d);

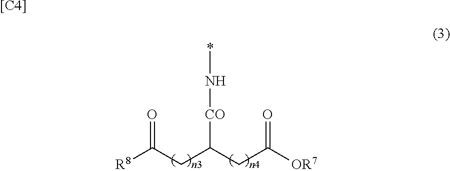

wherein, in formula (3), R⁷ and R⁸ each independently represent an alkyl group having 1 to 10 carbon atoms, n3 and n4 each independently represent an integer of 0 to 2, and * represents a linking site with a residue obtained by removing the blocked isocyanate group from the structural unit (d).
   [6]

The copolymer according to any one of aspects [1] to [5], further comprising a different structural unit (e) other than the structural units (a) to (d),
wherein the structural unit (e) is a structural unit derived from an alkyl (meth)acrylate in which the number of carbon atoms in an alkyl group is 1 to 12.
   [7]

The copolymer according to any one of aspects [1] to [6], wherein an acid value is 10 to 300 KOH mg/g.

[8]

The copolymer according to any one of aspects [1] to [7], wherein the copolymer comprises 3 to 40 mol % of the structural unit (b).

[9]

The copolymer according to any of aspects [1] to [8], wherein a weight average molecular weight is 1000 to 50000, and
an ethylenically unsaturated group equivalent is 300 to 8000 g/mol.
   [10]

A photosensitive resin composition comprising:
a copolymer (A) that is the copolymer according to any one of aspects [1] to [9];
a reactive diluent (B);
a photopolymerization initiator (C); and
a solvent (D).
   [11]

The photosensitive resin composition according to aspect [10], comprising:
10 parts by mass to 90 parts by mass of the copolymer (A),
10 parts by mass to 90 parts by mass of the reactive diluent (B),
0.1 parts by mass to 30 parts by mass of the photopolymerization initiator (C), and
30 parts by mass to 1,000 parts by mass of the solvent (D), based on 100 parts by mass of the total of the copolymer (A) and the reactive diluent (B).
   [12]

A photosensitive coloring composition comprising:
the photosensitive resin composition according to aspect [10] or [11]; and
a coloring agent (E).
   [13]

The photosensitive coloring composition according to aspect [12], comprising:
10 parts by mass to 90 parts by mass of the copolymer (A),
10 parts by mass to 90 parts by mass of the reactive diluent (B),
0.1 parts by mass to 30 parts by mass of the photopolymerization initiator (C),
30 parts by mass to 1,000 parts by mass of the solvent (D), and
3 parts by mass to 80 parts by mass of the coloring agent (E), based on 100 parts by mass of the total of the copolymer (A) and the reactive diluent (B).
   [14]

A resin cured film comprising a cured product of the photosensitive resin composition according to aspect [10] or [11].

[15]

A resin cured film comprising a cured product of the photosensitive coloring composition according to aspect [12] or [13].

[16]

A color filter comprising a coloring pattern comprising a cured product of the photosensitive coloring composition according to aspect [12] or [13].

[17]

An image display element comprising the color filter according to aspect [16].

### Advantageous of Effects of Invention

According to the present invention, it is possible to provide a copolymer that contributes to improvement in developability and imparts a resin cured film having excellent solvent resistance, and a photosensitive resin composition and a photosensitive coloring composition for which the copolymer is used. In addition, it is possible to provide a resin cured film that is obtained by curing the photosensitive resin composition or the photosensitive coloring composition and has excellent solvent resistance and a color filter and an image display element comprising the color filter.

### DESCRIPTION OF EMBODIMENTS

Hereinafter, embodiments of the present invention will be described in detail. However, the present invention is not limited to the following embodiments.

In the present specification, when “to” is used for a numerical range, the numerical values at both ends are an upper limit value and a lower limit value, respectively, and are included in the numerical range.

In the present specification, “(meth)acrylic acid” means methacrylic acid or acrylic acid, “(meth)acrylate” means acrylate or methacrylate, and “(meth)acryloyloxy” means acryloyloxy or methacryloyloxy.

In the present specification, “ethylenically unsaturated bond” means a double bond formed between carbon atoms except for carbon atoms forming an aromatic ring, and “ethylenically unsaturated group” means a group having an ethylenically unsaturated bond.

In the present specification, “structural unit” means a unit derived from a polymerizable compound used as a monomer or a unit obtained by additionally modifying the unit derived from the polymerizable compound used as a monomer.

### (Copolymer (A))

The copolymer (A) of one embodiment contains a structural unit (a) having an acid group and a structural unit (b) having a group represented by the following formula (1-1) or the following formula (1-2). Since the copolymer (A) has the structural unit (b) having an ethylenically unsaturated group, good photocurability can be obtained when the copolymer (A) is used in a photosensitive resin composition, and low-temperature curability improves. In addition, when the copolymer (A) is used together with a reactive diluent (B) described below, the ethylenically unsaturated group of the structural unit (b) reacts with the reactive diluent (B), and good adhesion of a cured film to a base material is obtained.

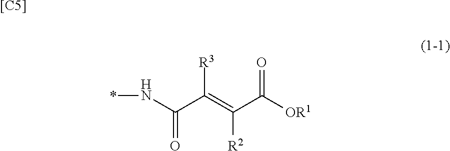

in formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group of formula (1-1) from the structural unit (b).

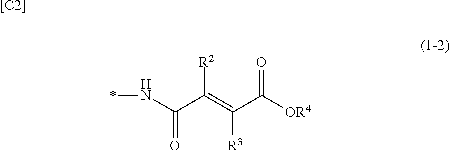

in formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group of formula (1-2) from the structural unit (b).

The copolymer (A) may further contain a structural unit (c) having a hydroxy group and a structural unit (d) having a blocked isocyanate group, as necessary. The copolymer (A) may further contain a different structural unit (e) other than the structural units (a) to (d), as necessary.

### [Structural Unit (a) Having Acid Group]

The structural unit (a) having an acid group (also simply referred to as “structural unit (a)”) is not particularly limited, as long as the structural unit does not have an ethylenically unsaturated group and has an acid group. Since the copolymer (A) has the structural unit (a) having an acid group, good alkali developability can be obtained when the copolymer (A) is used in a photosensitive resin composition. Examples of the acid group include carboxy groups, sulfo groups, phospho groups, and the like. Among these acid groups, a carboxy group is preferable as the acid group in the structural unit (a) from the viewpoint of ease of acquisition.

The structural unit (a) having an acid group is preferably a structural unit derived from a monomer (m-a) having an acid group and an ethylenically unsaturated bond (hereinafter also simply referred to as the monomer (m-a)). Specific examples of the monomer (m-a) include unsaturated carboxylic acids such as (meth)acrylic acid, α-bromo(meth)acrylic acid, β-furyl(meth)acrylic acid, crotonic acid, propiolic acid, cinnamic acid, α-cyanocinnamic acid, maleic acid, maleic anhydride, monomethyl maleate, monoethyl maleate, monoisopropyl maleate, fumaric acid, itaconic acid, itaconic anhydride, citraconic acid, and citraconic anhydride or anhydrides thereof; unsaturated sulfonic acids such as 2-acrylamido-2-methylpropanesulfonic acid, tert-butylacrylamido sulfonic acid, and p-styrenesulfonic acid; unsaturated phosphonic acids such as vinylphosphonic acid; and the like. The monomer (m-a) is preferably an unsaturated carboxylic acid or an anhydride thereof, more preferably (meth)acrylic acid or (meth)acrylate having a carboxylic acid group, and still more preferably (meth)acrylic acid.

The monomer (m-a) having an acid group and an ethylenically unsaturated bond may be used singly or two or more thereof may be used in combination.

The content of the structural unit (a) is preferably 5 to 50 mol %, more preferably 8 to 40 mol %, and still more preferably 10 to 30 mol % in all of the structural units of the copolymer (A). When the content of the structural unit (a) is 5 mol % or more, good developability of a photosensitive resin composition for which the copolymer (A) is used can be obtained. When the content of the structural unit (a) is 50 mol % or less, the content of the structural unit (b) can be sufficiently ensured, and an effect attributed to the structural unit (b) can be thus sufficiently ensured.

### [Structural Unit (b) Having Group Represented by Formula (1-1) or Formula (1-2)]

The structural unit (b) having a group represented by formula (1-1) or formula (1-2) (also simply referred to as “structural unit (b)”) is a structural unit having a group represented by the following formula (1-1) or the following formula (1-2).

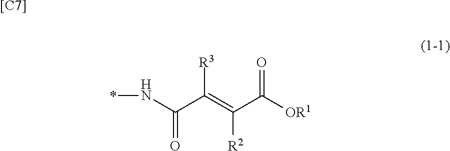

in formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group of formula (1-1) from the structural unit (b).

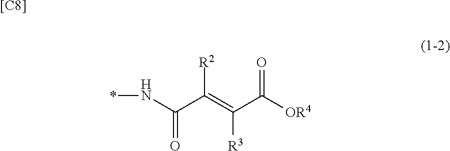

in formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group of formula (1-2) from the structural unit (b).

Groups represented by formula (1-1) may not be one kind. R¹'s in each structural unit may be different from each other, R²'s in each structural unit may be different from each other, and R³'s in each structural unit may be different from each other. This is also true for the group represented by formula (1-2).

In formula (1-1) and formula (1-2), R¹ and R⁴ are each independently a hydrogen atom or a hydrocarbon group having 1 to 20 carbon atoms and preferably a hydrocarbon group having 1 to 5 carbon atoms. In particular, because a conversion reaction from a structural unit (pb) described below to the structural unit (b) having the group represented by formula (1-1) or formula (1-2) is likely to occur, a hydrocarbon group having 1 to 3 carbon atoms is more preferable. R¹ and R⁴ are preferably an alkyl group having 1 to 5 carbon atoms, preferably a methyl group or an ethyl group, and particularly preferably an ethyl group. R¹ and R⁴ may be the same as or different from each other. R¹ and R⁴ are preferably the same as each other because a monomer (m-pb) described below can be easily produced.

In formula (1-1) and formula (1-2), R² and R³ are each independently a hydrogen atom or a hydrocarbon group having 1 to 20 carbon atoms and preferably a hydrogen atom or a hydrocarbon group having 1 to 5 carbon atoms. In particular, because the conversion reaction from the structural unit (pb) described below to the structural unit (b) having the group represented by formula (1-1) or formula (1-2) is likely to occur, a hydrogen atom or a methyl group is more preferable, and a hydrogen atom is particularly preferable. R² and R³ may be the same as or different from each other. R² and R³ are preferably the same as each other, because the monomer (m-pb) described below can be easily produced.

The structural unit (b) can be obtained by performing a dealcoholization reaction and a decarboxylation reaction of the structural unit (pb) having the group represented by the following formula (1) (also simply referred to as “structural unit (pb)”) in a solvent (PD) using a basic catalyst.

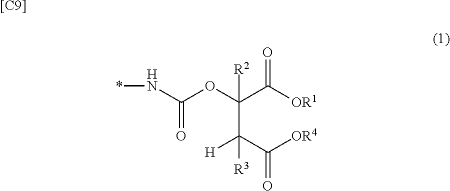

in formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group of formula (1) from the structural unit (pb).

The structural unit (pb) is a structural unit derived from a monomer (m-pb) having the group represented by formula (1) (also simply referred to as “monomer (m-pb)”). The structural unit (pb) may be used singly or two or more thereof may be used in combination.

The monomer (m-pb) is a monomer having an ethylenically unsaturated bond and the group represented by the formula (1).

In formula (1), R¹, R², R³, and R⁴ are the same as those described above.

Examples of the monomer (m-pb) include compounds obtained by subjecting an isocyanate group in an isocyanate compound having an ethylenically unsaturated group, such as a vinyl group or a (meth)acryloyloxy group, in the molecule and a hydroxy group in a hydroxy group-containing compound represented by the following formula (4) to a urethane formation reaction.

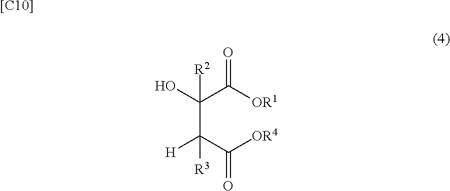

in formula (4), R¹, R², R³, and R⁴ are the same as R¹, R², R³, and R⁴ in formula (1).

As a method for subjecting the isocyanate compound having an ethylenically unsaturated group and the hydroxy group-containing compound represented by formula (4) to a urethane formation reaction, a known conventional method can be used.

The above-described urethane formation reaction can be performed regardless of the presence or absence of a solvent. A solvent that is used when the urethane formation reaction is performed using a solvent needs to be a solvent inert to isocyanate groups, and known solvents can be used.

Generally, the urethane formation reaction is preferably performed at a temperature of −10° C. or higher and 90° C. or lower, more preferably performed at a temperature of 5° C. or higher and 70° C. or lower, and still more preferably performed at a temperature of 10° C. or higher and 40° C. or lower.

At the time of performing the urethane formation reaction, a urethane formation catalyst, such as dibutyltin dilaurate, a polymerization inhibitor, such as phenothiazine, hydroquinone monomethyl ether, or 2,6-di-tert-butyl-4-methylphenol (BHT), and the like may be used, as necessary.

Examples of the isocyanate compound having an ethylenically unsaturated group that is used as a raw material of the monomer (m-pb) include isocyanate compounds represented by the following formula (5).

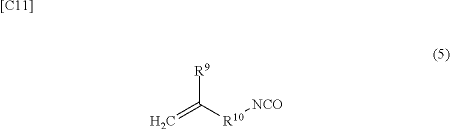

in formula (5), R⁹ represents a hydrogen atom or a methyl group, and R¹⁰ represents —CO—, —COOR¹¹— (wherein R¹¹ is an alkylene group having 1 to 6 carbon atoms) or —COO—R¹²O—CONH—R¹³— (wherein R¹² is an alkylene group having 2 to 6 carbon atoms, R¹³ is an alkylene group having 2 to 12 carbon atoms or an arylene group having 6 to 12 carbon atoms, which may have a substituent).

In the isocyanate compounds represented by formula (5), R¹⁰ is preferably —COOR¹¹— from the viewpoint of ease of preparation of the isocyanate compound, and R¹¹ is more preferably an alkylene group having 1 to 4 carbon atoms.

Specific examples of the isocyanate compounds represented by formula (5) include 2-isocyanatoethyl (meth)acrylate, 2-isocyanatopropyl (meth)acrylate, 3-isocyanatopropyl (meth)acrylate, 2-isocyanato-1-methylethyl (meth)acrylate, 2-isocyanato-1,1-dimethylethyl (meth)acrylate, 4-isocyanatocyclohexyl (meth)acrylate, methacryloyl isocyanate, and the like.

As the isocyanate compound that is used as a raw material of the monomer (m-pb), a reaction product obtained by reacting a hydroxyalkyl (meth)acrylate and a diisocyanate compound in an equimolar ratio (hydroxyalkyl (meth)acrylate:diisocyanate compound=1 mol:1 mol) may be used.

An alkyl group of the hydroxyalkyl (meth)acrylate is preferably an ethyl group or a n-propyl group, and more preferably an ethyl group from the viewpoint of ease of preparation of the isocyanate compound and the simplicity of the reaction.

Examples of the diisocyanate compound include hexamethylenediisocyanate, 2,4-(or 2,6-)tolylene diisocyanate (TDI), 4,4′-diphenylmethane diisocyanate (MDI), 3,5,5-trimethyl-3-isocyanatomethylcyclohexyl isocyanate (IPDI), m-(or p-)xylene diisocyanate, 1,3-(or 1,4-)bis(isocyanatomethyl)cyclohexane, lysine diisocyanate, and the like.

Additional examples of the isocyanate compound that is used as the raw material of the monomer (m-pb) include 1,1-bis(methacryloyloxymethyl)methyl isocyanate, 1,1-bis(methacryloyloxymethyl)ethyl isocyanate, 1,1-bis(acryloyloxymethyl)methyl isocyanate, 1,1-bis(acryloyloxymethyl)ethyl isocyanate, and the like.

As the isocyanate compound that is used as the raw material of the monomer (m-pb), from the viewpoint of low-temperature curability, an isocyanate group-containing (meth)acrylate is preferable, 2-isocyanatoethyl (meth)acrylate, 2-isocyanatopropyl (meth)acrylate, 3-isocyanatopropyl (meth)acrylate, 2-isocyanato-1-methylethyl (meth)acrylate, 1,1-bis(methacryloyloxymethyl)ethyl isocyanate, 2-isocyanato-1,1-dimethylethyl (meth)acrylate, 4-isocyanatocyclohexyl (meth)acrylate, and methacryloyl isocyanate are more preferable, and 2-isocyanatoethyl (meth)acrylate, 2-isocyanatopropyl (meth)acrylate, and 1,1-bis(methacryloyloxymethyl)ethyl isocyanate are more preferable.

Examples of the hydroxy group-containing compound represented by formula (4) that is used as a raw material of the monomer (m-pb) include malate, 2-methylmalate, 3-methylmalate, 2,3-dimethylmalate, and the like. Among these, malate is preferable from the viewpoint of ease of the conversion reaction to the structural unit (b) having the group represented by formula (1-1) or formula (1-2) and ease of acquisition.

The numbers of carbon atoms in two ester sites contained in the hydroxy group-containing compound represented by the formula (4) (the numbers of carbon atoms of R¹ and R⁴ in-COOR¹ and COOR⁴) are each 1 to 20, preferably 1 to 5, and more preferably 1 to 3.

The hydroxy group-containing compound represented by formula (4) is particularly preferably diethyl malate from the viewpoint of ease of acquisition.

Specifically, the monomer (m-pb) is preferably one or two or more selected from 2-[(diethyl malate)carbonylamino] ethyl acrylate. [(diethyl malate)carbonylamino] methyl acrylate, 2-[(diethyl malate)carbonylamino]propyl acrylate, and 2-[(diethyl malate) carbonylamino] butyl acrylate, and from the viewpoint of ease of production, 2-[(diethyl malate) carbonylamino] ethyl acrylate is particularly preferable.

The content of the structural unit (b) is preferably 3 mol % or more, more preferably 5 mol % or more, and still more preferably 10 mol % or more in all of the structural units of the copolymer (A). The content of the structural unit (b) is preferably 40 mol % or less, more preferably 35 mol % or less, and still more preferably 30 mol % or less in all of the structural units of the copolymer (A). The combination of these lower limit values and upper limit values may be any combination. The content of the structural unit (b) is preferably 3 to 40 mol %, more preferably 5 to 35 mol %, and still more preferably 10 to 30 mol % in all of the structural units of the copolymer (A). When the content of the structural unit (b) is 3 mol % or more, good low-temperature curability and developability of a photosensitive resin composition for which the copolymer (A) is used can be obtained. When the content of the structural unit (b) is 40 mol % or less, the content of the structural unit (a) can be sufficiently ensured, and sufficient developability can be obtained. The content of the structural unit (b) is a value calculated from the charge ratio of the monomer (m-pb) used at the time of producing a resin precursor (PA) described below and all monomers used at the time of producing the resin precursor (PA). That is, the content of the structural unit (b) also includes the content of structural unit (pb).

### [Structural Unit (c) Having Hydroxy Group]

The structural unit (c) having a hydroxy group (also simply referred to as “structural unit (c)”) is not limited, as long as the structural unit does not have an acid group, an ethylenically unsaturated group, and a blocked isocyanate group and has a hydroxy group. When the copolymer (A) has the structural unit (c) having a hydroxy group, cross-linking with the structural unit (d) having a blocked isocyanate group, which will be described below, progresses during heating. Therefore, when the copolymer (A) is used for a photosensitive resin composition, good solvent resistance of a cured product can be obtained even in thermal curing under low-temperature conditions.

The structural unit (c) having a hydroxy group is preferably a structural unit derived from a monomer (m-c) having a hydroxy group and an ethylenically unsaturated group (hereinafter also simply referred to as the monomer (m-c)). Specific examples of the monomer (m-c) include (meth)acrylic acid ester derivatives having a hydroxy group, and specifically include hydroxyalkyl (meth)acrylates, such as 2-hydroxyethyl (meth)acrylate, 2-hydroxypropyl (meth)acrylate, 2-hydroxy butyl (meth)acrylate, 2,3-dihydroxypropyl (meth)acrylate, and 4-hydroxy butyl (meth)acrylate; 2-hydroxy-3-phenoxypropyl (meth)acrylate, and the like. Among these, hydroxyalkyl (meth)acrylates are preferable from the viewpoint of reactivity at the time of synthesizing the copolymer (A), low-temperature curability of a photosensitive resin composition containing the copolymer (A), and ease of acquisition. The hydroxyalkyl (meth)acrylate is preferably 2-hydroxyethyl (meth)acrylate, 2-hydroxypropyl (meth)acrylate, and 4-hydroxy butyl (meth)acrylate, and 4-hydroxy butyl (meth)acrylate is more preferable from the viewpoint of reducing the glass transition temperature of the copolymer (A).

The monomer (m-c) having a hydroxy group and an ethylenically unsaturated group may be used singly or two or more thereof may be used in combination.

The content of the structural unit (c) is preferably 3 to 40 mol %, more preferably 5 to 30 mol %, and still more preferably 8 to 25 mol % in all of the structural units of the copolymer (A). When the content of the structural unit (c) is 3 mol % or more, a sufficient amount of cross-linking between the hydroxy group of the structural unit (c) and the blocked isocyanate group of the structural unit (d) can be ensured. As a result, the low-temperature curability of a photosensitive resin composition for which the copolymer (A) is used improves. When the content of the structural unit (c) is 40 mol % or less, because the contents of the structural unit (a) and the structural unit (b) can be sufficiently ensured, sufficient developability of a cured product can be obtained. In addition, because the content of the structural unit (d) can be sufficiently ensured, the amount of cross-linking with the structural unit (c) can be sufficiently ensured.

### [Structural Unit (d) Having Blocked Isocyanate Group]

The structural unit (d) having a blocked isocyanate group (also simply referred to as “structural unit (d)”) is not particularly limited, as long as the structural unit does not have an acid group and an ethylenically unsaturated group, is a structural unit that does not correspond to the structural unit (pb), and is a structural unit having a blocked isocyanate group. When the copolymer (A) has the structural unit (d) having a blocked isocyanate group, cross-linking with the structural unit (c) having a hydroxy group progresses during heating. A cross-link is formed by, for example, a reaction of an isocyanate group generated due to dissociation of a blocking agent and a hydroxy group. When the blocking agent is a compound having a carboxylic acid alkyl ester structure, a cross-link can be formed by ester exchange between a carboxylic acid alkyl ester structure described below and a hydroxy group without causing dissociation of the blocking agent. Therefore, when the copolymer (A) is used for a photosensitive resin composition, good solvent resistance of a cured product can be obtained even in thermal curing under low-temperature conditions.

The structural unit (d) having a blocked isocyanate group has a structure in which an isocyanate group is blocked with a blocking agent. The reaction between the isocyanate group and the blocking agent can be performed regardless of the presence or absence of a solvent. When a solvent is used, a solvent that is inert to the isocyanate group needs to be used. At the time of a blocking reaction, an organic metal salt of tin, zinc, lead, or the like, a tertiary amine, or the like may be used as a catalyst. Generally, the blocking reaction can be performed at −20° C. to 150° C. but is preferably performed at 0° C. to 100° C.

Examples of the blocking agent that blocks the isocyanate group include lactams compounds, such as ε-caprolactam, δ-valerolactam. γ-butylolactam, and β-propiolactam; alcohol compounds such as methanol, ethanol, propanol, butanol, ethylene glycol, 2-methoxy ethanol, ethylene glycol monobutyl ether, methyl carbitol, benzyl alcohol, phenoxyethanol, furfuryl alcohol, and cyclohexanol; butylphenols such as phenol, cresol, 2,6-xylenol, 3,5-xylenol, ethylphenol, o-isopropylphenol, and p-tert-butylphenol, phenol compounds such as p-tert-octyl phenol, nonylphenol, dinonylphenol, styrenated phenol, methyl 2-hydroxybenzoate, methyl 4-hydroxybenzoate, thymol, 1-naphthol, p-nitrophenol, and p-chlorophenol; active methylene compounds such as dimethyl malonate, diethyl malonate, methyl acetoacetate, ethyl acetoacetate, and acetyl acetone; mercaptan compounds such as butyl mercaptans, thiophenol, and tert-dodecyl mercaptans; amine compounds such as diphenylamine, phenylnaphthyl amine, aniline, and carbazole; acid amide compounds such as acetanilide, acetanisidide, acetamide, and benzamide; imide compounds such as succinimide, and maleic imide; imidazole compounds such as imidazole, 2-methylimidazole, and 2-ethylimidazole; pyrazole compounds such as pyrazole and 3,5-dimethylpyrazole; urea compounds such as urea, thiourea, and ethylene urea; carbamic acid compounds such as phenyl N-phenylcarbamate and 2-oxazolidone; imine compounds such as ethylenimine and polyethylenimine; oxime compounds such as formaldoxime, acetaldoxime, acetoxime, methyl ethyl ketoxime, methyl isobutyl ketoxime, and cyclohexanone oxime; bisulfites such as sodium bisulfite and potassium bisulfite; and the like.

The blocking agent may be used singly or two or more thereof may be used in combination.

In one embodiment, as the blocking agent, from the viewpoint of improving the low-temperature curability and solvent resistance as a photosensitive resin composition, a blocking agent with which the dissociation rate of the blocked isocyanate group when thermally treated at 100° C. for 30 minutes is 5 to 99 mass % is preferable, one or more selected from the group consisting of 3,5-dimethylpyrazole, methyl ethyl ketoxime, methyl 4-hydroxy benzoate, methyl 2-hydroxy benzoate, and 3,5-xylenol are more preferable, and 3,5-dimethylpyrazole is still more preferable.

In the present specification, the dissociation rate of the blocked isocyanate group is a value obtained by measuring the mass reduction ratio of the blocked isocyanate group-containing compound by HPLC analysis after a n-octanol solution having a concentration of a blocked isocyanate group-containing compound of 20 mass % is prepared, and 1 mass %-equivalent dibutyltin laurate and 3 mass %-equivalent phenothiazine (polymerization inhibitor) are added thereto and then heated at 100° C. for 30 minutes. As the blocked isocyanate group-containing compound, a compound obtained by blocking the isocyanate group of 2-isocyanatoethyl acrylate with a blocking agent, which is the measurement target, is used. When the blocked isocyanate group-containing compound having a dissociation rate in the above-described range is used, the stability of the copolymer (A) at the time of synthesis can be sufficiently ensured, the baking temperature at the time of preparing a cured film can be set to be sufficiently low, and the solvent resistance of the cured film can be sufficiently ensured.

In one embodiment, as the blocking agent, from the viewpoint of improving low-temperature curability and solvent resistance as a photosensitive resin composition, a blocking agent having a carboxylic acid alkyl ester structure is also preferable. In this case, the structural unit (d) having a blocked isocyanate group has a carboxylic acid alkyl ester structure. The carboxylic acid alkyl ester structure means a structure having an alkyloxycarbonyl group, and a structure having an alkyloxycarbonyl group having 1 to 10 carbon atoms in an alkyl group is preferable. The alkyloxycarbonyl group is subjected to an ester exchange with the hydroxy group of the structural unit (c) when a photosensitive resin composition containing the copolymer (A) is heated and forms a crosslinked structure. Therefore, a photosensitive resin composition for which the copolymer (A) containing a structural unit having a carboxylic acid alkyl ester structure is used is capable of imparting a cured film having excellent solvent resistance even when cured at low temperatures of 50° C. to 150° C.

The structural unit having a carboxylic acid alkyl ester structure is more preferably a structural unit having a group represented by the following formula (2) or a group represented by the following formula (3).

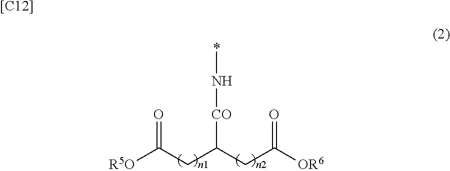

in formula (2), R⁵ and R⁶ each independently represent an alkyl group having 1 to 10 carbon atoms, n1 and n2 each independently represent an integer of 0 to 2, and * represents a linking site with a residue obtained by removing the blocked isocyanate group from the structural unit (d).

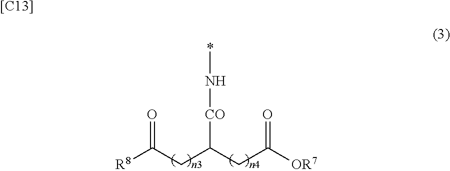

in formula (3), R⁷ and R⁸ each independently represent an alkyl group having 1 to 10 carbon atoms, n3 and n4 each independently represent an integer of 0 to 2, and * represents a linking site with a residue obtained by removing the blocked isocyanate group from the structural unit (d).

Groups represented by formula (2) may not be one kind. R⁵'s in each structural unit may be different from each other, R⁶'s in each structural unit may be different from each other, n1's in each structural unit may be different from each other, and n2's in each structural unit may be different from each other. This is also true for the group represented by formula (3).

R⁵ and R⁶ in formula (2) are each independently an alkyl group having 1 to 10 carbon atoms. R⁵ and R⁶ are each independently preferably an alkyl group having 2 to 6 carbon atoms and more preferably an alkyl group having 2 or 3 carbon atoms, and R⁵ and R⁶ are both most preferably ethyl groups.

When R⁵ and R⁶ are ethyl groups, at the time of thermally curing a photosensitive resin composition containing the copolymer (A), R⁵ and R⁶ are subjected to an ester exchange with the hydroxy group of the structural unit (c) to generate ethanol. The ethanol generated at the time of the thermal curing of the photosensitive resin composition is easily evaporated and removed by heating for thermally curing the photosensitive resin composition and is thus preferable.

n1 and n2 in formula (2) each independently represent an integer of 0 to 2, n1 and n2 are each independently preferably 0 or 1, and both are more preferably 0.

R⁷ and R⁸ in formula (3) are each independently an alkyl group having 1 to 10 carbon atoms. R⁷ is preferably an alkyl group having 2 to 6 carbon atoms, more preferably an alkyl group having 2 or 3 carbon atoms, and still more preferably an ethyl group.

When R⁷ is an ethyl group, at the time of thermally curing a photosensitive resin composition containing the copolymer (A), R⁷ is subjected to an ester exchange with the hydroxy group of the structural unit (c) to generate ethanol. The ethanol generated at the time of the thermal curing of the photosensitive resin composition is easily evaporated and removed by heating for thermally curing the photosensitive resin composition and is thus preferable.

R⁸ is preferably an alkyl group having 1 to 6 carbon atoms, more preferably an alkyl group having 1 to 3 carbon atoms, and still more preferably a methyl group.

n3 and n4 in formula (3) each independently represent an integer of 0 to 2, n3 and n4 are each independently preferably 0 or 1, and both are more preferably 0.

From the viewpoint of ease of the progress of the ester exchange with the hydroxy group of the structural unit (c) and low-temperature curability as a photosensitive resin composition, the structural unit (d) preferably has the group represented by formula (2).

The structural unit (d) having a blocked isocyanate group is preferably a structural unit derived from a monomer (m-d) having a blocked isocyanate group and an ethylenically unsaturated bond (also simply referred to as the monomer (m-d)). The monomer (m-d) may be used singly or two or more thereof may be used in combination. Specific examples of a group having an ethylenically unsaturated bond include a vinyl group, a (meth)acryloyloxy group, and the like.

Examples of the monomer (m-d) include reaction products of an isocyanate compound having an ethylenically unsaturated group and a blocking agent. As the isocyanate compound having an ethylenically unsaturated group, the same compounds as the isocyanate compounds used as the raw material of the monomer (m-pb) can be used.

The structural unit having the group represented by formula (2) or formula (3) is preferably a structural unit derived from a monomer having the group represented by formula (2) or formula (3) and an ethylenically unsaturated bond. Specific examples of the group having an ethylenically unsaturated bond include a vinyl group, a (meth)acryloyloxy group, and the like.

Examples of the monomer having the group represented by formula (2) or formula (3) and an ethylenically unsaturated bond include reaction products of an isocyanate compound having an ethylenically unsaturated group and a malonic acid diester or an acetoacetate.

As the isocyanate compound having an ethylenically unsaturated group, the same compound as the isocyanate compound used as the raw material of the monomer (m-pb) can be used.

Examples of the malonic acid diester include dimethyl malonate, diethyl malonate, di(n-propyl) malonate, di(i-propyl) malonate, and the like, and from the viewpoint of ease of acquisition, the cost, and the quality, diethyl malonate and dimethyl malonate are preferable.

Examples of the acetoacetate include methyl acetoacetate, ethyl acetoacetate, and the like.

Specific examples of the monomer having the group represented by formula (2) and an ethylenically unsaturated bond include KARENZ (trademark) MOI-DEM (manufactured by Showa Denko K.K.) and KARENZ AOI-DEM (manufactured by Showa Denko K.K.).

The reaction between the isocyanate compound having an ethylenically unsaturated group and a malonic diester or acetoacetate can be performed regardless of the presence or absence of a solvent. When the reaction is performed using a solvent, a solvent inert to the isocyanate group is used. At the time of the reaction, an organic metal salt of tin, zinc, lead, or the like, a tertiary amine, or the like may be used as a catalyst.

The reaction can be generally performed at a temperature of −20° C. to 150° C. and is preferably performed at a temperature of 25° C. to 130° C. When the temperature of the reaction is −20° C. or higher, a sufficient reaction rate can be obtained. On the other hand, when the temperature of the reaction is 150° C. or lower, gelation by the polymerization of a raw material having C═C (double bond) can be prevented.

The content of the structural unit (d) is preferably 5 to 45 mol %, more preferably 10 to 40 mol %, and still more preferably 15 to 35 mol % in all of the structural units of the copolymer (A). When the content of the structural unit (d) is 5 mol % or more, a sufficient amount of cross-linking between the blocked isocyanate group of the structural unit (d) and the hydroxy group of the structural unit (c) can be ensured. As a result, the low-temperature curability of a photosensitive resin composition for which the copolymer (A) is used improves. When the content of the structural unit (d) is 45 mol % or less, because the contents of the structural unit (a) and the structural unit (b) can be sufficiently ensured, sufficient developability of a cured product can be obtained. In addition, the content of the structural unit (c) can be sufficiently ensured, and the amount of cross-linking with the structural unit (d) can be sufficiently ensured.

[Different Structural Unit (e) Other than Structural Units (a) to (d)]

The copolymer (A) may contain a different structural unit (e) other than the structural units (a) to (d) (also simply referred to as “structural unit (e)”), that is, a structural unit derived from monomers other than the monomers (m-a), (m-pb). (m-c), and (m-d), as necessary. The structural unit (e) is a structural unit, which does not have an acid group, an ethylenically unsaturated group, a hydroxy group, and a blocked isocyanate group, other than the structural units (a) to (d) and the structural unit (pb). When the copolymer (A) has the structural unit (e), it is possible to impart an additionally required function.

The different structural unit (e) is a structural unit derived from a different monomer (m-e) having a ethylenically unsaturated group copolymerizable with the monomers (m-a). (m-pb). (m-c), and (m-d) (also simply referred to as the monomer (m-e)). Specific examples thereof include aromatic vinyl compounds, cyclic olefins having a norbornene structure, dienes, (meth)acrylic acid esters, amide (meth)acrylate, vinyl compounds, unsaturated dicarboxylic acid diesters, monomaleimides, glycidyl (meth)acrylate, (meth)acrylic acid anilide, (meth)acrylonitrile, acrolein, and the like.

Examples of the aromatic vinyl compounds include styrene, α-methylstyrene, o-vinyltoluene, p-vinyltoluene, o-chlorostyrene, m-chlorostyrene, methoxystyrene, p-nitrostyrene, p-cyanostyrene, p-acetylaminostyrene, and the like.

Examples of the cyclic olefins having a norbornene structure include norbornene (bicyclo[2.2.1]hept-2-ene), 5-methylbicyclo[2.2.1]hept-2-ene, tetracyclo[4.4.0.1^{2,5}. 1^{7,10}]dodeca-3-ene, 8-ethyltetracyclo[4.4.0.1^{2,5}. 1^{7,10}]dodeca-3-ene, dicyclopentadiene, tricyclo[5.2.1.0^{2,6}]deca-8-ene, tricyclo[4.4.0.1^{2,5}]undeca-3-ene, tricyclo[6.2.1.0^{1,8}]undeca-9-ene, tetracyclo[4.4.0.1^{2,5}. 1^{7,10} 0^{1,6}]dodeca-3-ene, 8-ethylidenetetracyclo[4.4.0.1^{2,5}. 1^{7,12}]dodeca-3-ene, and pentacyclo[6.5.1.1^{3,6}.0^{2,7}. 0^{9,13}]pentadeca-4-ene, and the like.

Examples of the dienes include butadiene, isoprene, chloroprene, and the like.

Examples of the (meth)acrylic acid esters include methyl (meth)acrylate, ethyl (meth)acrylate, isopropyl (meth)acrylate, tert-butyl (meth)acrylate, pentyl (meth)acrylate, benzyl (meth)acrylate, isoamyl (meth)acrylate, 2-ethylhexyl (meth)acrylate, lauryl (meth)acrylate, dodecyl (meth)acrylate, cyclohexyl (meth)acrylate, methylcyclohexyl (meth)acrylate, rosin (meth)acrylate, norbornyl (meth)acrylate, 5-ethyl norbornyl (meth)acrylate, dicyclopentenyl (meth)acrylate, dicyclopentanyl (meth)acrylate, dicyclopentenyl oxyethyl acrylate, isobornyl (meth)acrylate, adamantyl (meth)acrylate, tetrahydrofurfuryl (meth)acrylate, 1,1,1-trifluoroethyl (meth)acrylate, perfluoroethyl (meth)acrylate, perfluoro-n-propyl (meth)acrylate, 3-(N,N-dimethylamino) propyl (meth)acrylate, triphenylmethyl (meth)acrylate, phenyl (meth)acrylate, cumyl (meth)acrylate, 4-phenoxyphenyl (meth)acrylate, phenoxyethyl (meth)acrylate, phenoxy polyethylene glycol (meth)acrylate, nonylphenoxy polyethylene glycol mono(meth)acrylate, biphenyloxyethyl (meth)acrylate, naphthalene (meth)acrylate, anthracene (meth)acrylate, and ethoxylated phenyl (meth)acrylate.

Examples of the amide (meth)acrylates include amide (meth)acrylate, N,N-dimethylamide (meth)acrylate, N,N-diisopropylamide (meth)acrylate, anthracenyl amide (meth)acrylate, and the like.

Examples of the vinyl compounds include vinyl chloride, vinylidene chloride, vinyl fluoride, vinylidene fluoride, N-vinylpyrrolidone, vinylpyridine, vinyl acetate, vinyltoluene, and the like.

Examples of the unsaturated dicarboxylic acid diesters include diethyl citraconate, diethyl maleate, diethyl fumarate, diethyl itaconate, and the like.

Examples of the monomaleimides include N-phenylmaleimide, N-cyclohexylmaleimide, N-laurylmaleimide, and the like.

Among these, from the viewpoint of ease of acquisition and reactivity at the time of synthesizing the copolymer (A), aromatic vinyl compounds, aromatic group-containing (meth)acrylate, and alkyl (meth)acrylates in which the number of carbon atoms in an alkyl group is 1 to 12 are preferable, styrene, benzyl (meth)acrylate, dicyclopentenyl (meth)acrylate, 2-ethylhexyl (meth)acrylate, and methyl (meth)acrylate are more preferable, and 2-ethylhexyl (meth)acrylate and methyl (meth)acrylate are still more preferable.

The monomer (m-e) may be used singly or two or more thereof may be used in combination.

When the copolymer (A) contains the structural unit (e), the content thereof is preferably 1 to 50 mol %, more preferably 3 to 45 mol %, and still more preferably 5 to 40 mol % in all of the structural units of the copolymer (A). When the content of the structural unit (e) is within the above-described range, additional functions by the structural unit (e) can be imparted, or functions obtained from the structural units (a) to (d) can be adjusted to be an appropriate range while the functions of the structural units (a) to (d) are sufficiently ensured.

### [Ethylenically Unsaturated Group Equivalent of Copolymer (A)]

The ethylenically unsaturated group equivalent of the copolymer (A) is preferably 300 g/mol or more, more preferably 500 g/mol or more, and still more preferably 1000 g/mol or more. The ethylenically unsaturated group equivalent of the copolymer (A) is preferably 8000 g/mol or less, more preferably 7000 g/mol or less, and still more preferably 5000 g/mol or less. The combination of these lower limit values and upper limit values may be any combination. The ethylenically unsaturated group equivalent of the copolymer (A) is preferably 300 to 8000 g/mol, more preferably 500 to 7000 g/mol, and still more preferably 1000 to 5000 g/mol. When the ethylenically unsaturated group equivalent is 300 g/mol or more, storage stability as a photosensitive resin composition is good. When the ethylenically unsaturated group equivalent is 8000 g/mol or less, the solvent resistance of a cured product is good even when a photosensitive resin composition is cured at a low temperature.

“Ethylenically unsaturated group equivalent” is the mass of the polymer per mole of the ethylenically unsaturated group of the polymer. The ethylenically unsaturated group equivalent (g/mol) of the copolymer (A) is obtained by dividing the mass of the copolymer (A) by the number of moles of the ethylenically unsaturated group contained in the copolymer (A).

In the present specification, when R² and R³ of formula (1-1) and formula (1-2) in the copolymer are all hydrogen atoms, the ethylenically unsaturated group equivalent is a value calculated from the conversion rate from the structural unit (pb) to the structural unit (b) that is calculated from the area ratio of an NMR spectrum acquired using an NMR device (for example, Bruker ULTRA SHIELD PLUS 400 (400 MHZ), Bruker Inc.) under the following conditions and the charge amounts of the monomers (m-a), (m-pb) and (m-c) to (m-e) used at the time of producing the resin precursors (PA) described below.

### (NMR Conditions)

Measurement method: ¹H-NMR
Lock Solvent: CDCl₃
Internal standard: TSP-d₄ (sodium trimethylsilyl propionate)=0 ppm
Temperature: Room temperature
Sample preparation: Powder specimen (20 mg)/CDCl₃ (1 mL)+TSP-d₄ (5 mg)

### (Sample Preparation Method)

20 mg of the dried copolymer is precisely weighed, dissolved in a 20 mL specimen bin by adding CDCl₃ (1 mL), shaken for five minutes with an ultrasonic washing machine, and then sealed in a 5 mmφ NMR sample tube, and NMR measurement is performed immediately after sampling.

The conversion rate from the structural unit (pb) to the structural unit (b) is calculated by the following expression based on the area ratio between the spectrum of “—CH₂—” of —CR²—CHR³—C(═O)— (that is, —CH—CH₂—C(═O)—) that is detected at 2.5 to 3.0 ppm and the spectra of —C(═O)—CR³—CR²—C(═O)— and —C(═O)—CR²—CR³—C(═O)— (that is, —C(═O)—CH═CH—C(═O)—) that are detected at 6.5 to 7.0 ppm.

$$Conversion rate from structural unit ( pb ) to structural unit ( b ) = ( - C ( = O ) - C H = C H - C ( = O ) - ) / \{ ( - C H - C {H}_{2} - C ( = O ) - ) + ( - C ( = O ) - C H = C H - C ( = O ) - ) \} \times 100 ( \% )$$

In the present specification, when the copolymer includes the structural unit (b) having the group represented by formula (1-1) or formula (1-2), in which at least one or both of R² and R³ are hydrocarbon groups having 1 to 20 carbon atoms, the ethylenically unsaturated group equivalent is a value calculated from the amount of a halogen bonding to the copolymer. The amount of the halogen bonding to the copolymer is evaluated as described below in accordance with JIS K 0070:1992.

That is, the dried copolymer is dissolved in chloroform, an appropriate amount of a Wijs solution is added thereto, and the solution is stirred. After that, the solution is put into a sealed state and left to stand in a dark place for one hour at 23° C. A potassium iodide solution and water are added to this solution and stirred, and the obtained solution is titrated with a sodium thiosulfate solution. Once the solution becomes slightly yellow, several drops of a starch solution are added thereto to titrate the solution until the blue color disappears. The ethylenically unsaturated bond in the copolymer reacts with halogen molecules at 1:1. Therefore, the ethylenically unsaturated group equivalent of the copolymer is determined by dividing the mass (g) of the copolymer used for the measurement by the amount of substance (mol) of the halogen molecules bonded to the copolymer that is determined by this measurement.

### [Acid Value of Copolymer (A)]

The acid value of the copolymer (A) is preferably 10 KOH mg/g or more, more preferably 15 KOH mg/g or more, and still more preferably 20 KOH mg/g or more. The acid value of the copolymer (A) is preferably 300 KOH mg/g or less, more preferably 200 KOH mg/g or less, and still more preferably 150 KOH mg/g or less. The combination of these lower limit values and upper limit values may be any combination. The acid value of the copolymer (A) is preferably 10 to 300 KOH mg/g, more preferably 15 to 200 KOH mg/g, and still more preferably 20 to 150 KOH mg/g. When the acid value is 10 KOH mg/g or more, developability is good. When the acid value is 300 KOH mg/g or less, storage stability is good.

The “acid value” is the acid value of a curable polymer measured in accordance with JIS K6901:2008 5.3. That is, the acid value means the number of milligrams of potassium hydroxide required to neutralize an acidic component contained in 1 g of the copolymer.

### [Weight Average Molecular Weight of Copolymer (A)]

The weight average molecular weight of the copolymer (A) is preferably 1000 or more, more preferably 3000 or more, and still more preferably 5000 or more. The weight average molecular weight of the copolymer (A) is preferably 50000 or less, more preferably 40000 or less, and still more preferably 30000 or less. The combination of these lower limit values and upper limit values may be any combination. The weight average molecular weight of the copolymer (A) is preferably 1000 to 50000, more preferably 3000 to 40000, and still more preferably 5000 to 30000. When the weight average molecular weight is 1000 or more, a defect such as a chip is less likely to be generated in a resin cured film after development at the time of using the copolymer (A) as a raw material of a photosensitive resin composition. When the weight average molecular weight is 50000 or less, the photosensitive resin composition containing the copolymer (A) takes a sufficiently short time for development and has excellent practicality.

In the present specification, the weight average molecular weight means a standard polystyrene-equivalent weight average molecular weight measured under the following conditions using gel permeation chromatography (GPC).
Column: two SHODEX (trademark) LF-804 (manufactured by Showa Denko K.K.) columns connected in series are used
Column temperature: 40° C.
Specimen: 0.2 mass % tetrahydrofuran solution of measurement target
Development solvent: Tetrahydrofuran
Detector: Differential refractometer (SHODEX (trademark) RI-71S) (manufactured by Showa Denko K.K.)
Flow rate: 1 mL/min

### [Blocked Isocyanate Group Equivalent of Copolymer (A)]

The blocked isocyanate group equivalent of the copolymer (A) is preferably 100 to 2000 g/mol, more preferably 200 to 1500 g/mol, still more preferably 300 to 1300 g/mol. When the blocked isocyanate group equivalent is 100 g/mol or more, the photosensitive resin composition containing the copolymer (A) has better developability. When the blocked isocyanate group equivalent is 2000 g/mol or less, the photosensitive resin composition containing the copolymer (A) enables the formation of a resin cured film having superior hardness.

“Blocked isocyanate group equivalent” is the mass of the polymer per mole of the blocked isocyanate group of the polymer. The blocked isocyanate group equivalent (g/mol) of the copolymer is obtained by dividing the mass of the copolymer by the number of moles of the blocked isocyanate group contained in the copolymer. In the present specification, as “blocked isocyanate group equivalent,” a theoretical value calculated from the charge amount of the monomer used at the time of producing the copolymer is used.

### [Hydroxy Group Equivalent of Copolymer (A)]

The hydroxy group equivalent of the copolymer (A) is preferably 200 to 5000 g/mol, more preferably 400 to 4000 g/mol, and still more preferably 800 to 3000 g/mol. When the hydroxy group equivalent is 200 g/mol or more, the photosensitive resin composition containing the copolymer (A) has better developability. When the hydroxy group equivalent is 5000 g/mol or less, the photosensitive resin composition containing the copolymer (A) enables the formation of a resin cured film having superior hardness.

“Hydroxy group equivalent” is the mass of the polymer per mole of the hydroxy group of the polymer. The hydroxy group equivalent (g/mol) of the copolymer is obtained by dividing the mass of the copolymer by the number of moles of hydroxy groups contained in the copolymer. In the present specification, as “hydroxy group equivalent,” a theoretical value calculated from the charge amount of the monomer used at the time of producing the copolymer is used.

### [Method for Producing Copolymer (A)]

### (Method for Producing Resin Precursor (PA))

The resin precursor (PA) can be produced by copolymerizing the monomers (m-a) and (m-pb) corresponding to the structural units (a) and (pb) to be contained in the resin precursor (PA), respectively. The proportions of the structural units (a) and (pb) contained in the resin precursor (PA) are the same as the proportions of the monomers (m-a) and (m-pb) in the total of all of the monomers used as the raw materials of the resin precursor (PA) (hereinafter sometimes referred to as “raw material monomers”).

Therefore, the proportion of each of the monomers (m-a) and (m-pb) in the raw material monomers used as the raw materials of the resin precursor (PA) is preferably 5 to 50 mol % for (m-a) and 3 to 40 mol % for (m-pb), more preferably 8 to 40 mol % for (m-a), and 5 to 35 mol % for (m-pb), and still more preferably 10 to 30 mol % for (m-a), and 10 to 30 mol % for (m-pb).

In the case of producing a resin precursor containing the structural unit (c) as the resin precursor (PA), as the raw material monomers of the resin precursor (PA), in addition to the monomers (m-a) and (m-pb), the monomer (m-c) may be further used. In that case, the proportion of the monomer (m-c) in the raw material monomers used as the raw materials of the resin precursor (PA) is preferably 3 to 40 mol %, more preferably 5 to 30 mol %, and still more preferably from 8 to 25 mol %.

In the case of producing a resin precursor containing the structural unit (d) as the resin precursor (PA), as the raw material monomers of the resin precursor (PA), in addition to the monomers (m-a) and (m-pb), the monomer (m-d) may be further used. In that case, the proportion of the monomer (m-d) in the raw material monomers used as the raw materials of the resin precursor (PA) is preferably 5 to 45 mol %, more preferably 10 to 40 mol %, and still more preferably 15 to 35 mol %.

In the case of producing a resin precursor containing the structural unit (e) as the resin precursor (PA), as the raw material monomers of the resin precursor (PA), in addition to the monomers (m-a) and (m-pb), the monomer (m-e) may be further used. In that case, the proportion of the monomer (m-e) in the raw material monomers used as the raw materials of the resin precursor (PA) is preferably 1 to 50 mol %, more preferably 3 to 45 mol %, and still more preferably 5 to 40 mol %.

The copolymerization reaction of the raw material monomers used at the time of producing the resin precursor (PA) (the monomers (m-a) and (m-pb), and the monomers (m-c), (m-d), and (m-e) used, as necessary) can be performed in the presence or absence of a polymerization solvent according to a radical polymerization method known in the technical field. Specifically, it is possible to use, for example, a method in which a raw material monomer solution is prepared by mixing the raw material monomers, a polymerization initiator, and a polymerization solvent and the raw material monomer solution is subjected to a polymerization reaction at a temperature of 50° C. to 100° C. for one to 20 hours in a nitrogen gas atmosphere.

As the polymerization solvent used at the time of producing the resin precursor (PA), solvents that can be used as the solvent (PD) described below can be used singly or two or more thereof can be used in combination.

When the raw material monomers contain the monomers (m-c) and (m-d), the temperature at which the raw material monomers are copolymerized is preferably lower than a temperature at which the dissociation rate of the blocked isocyanate group of the monomer (m-d) having the blocked isocyanate group and the ethylenically unsaturated bond becomes 80% or more in 30 minutes. This is to suppress gelation resulting from the reaction between an isocyanate group, which is generated by dissociation of the blocked isocyanate group of the monomer (m-d), and the hydroxy group of the hydroxy group-containing monomer (m-c) in the raw material monomer solution during the copolymerization reaction. The temperature at which the raw material monomers are copolymerized is more preferably lower than the temperature at which the dissociation rate of the blocked isocyanate group of the monomer (m-d) becomes 80% or more in 30 minutes by 20° C. to 50° C.

Specifically, the temperature at which the raw material monomers are copolymerized can be set to 50° C. to 100° C. and is preferably between 60° C. to 90° C. and more preferably 65° C. to 85° C.

Examples of the polymerization initiator used at the time of copolymerizing of the raw material monomers include 2,2′-azobis(2,4-dimethylvaleronitrile), azobisisobutyronitrile, azobisisovaleronitrile, benzoyl peroxide, t-butylperoxy-2-ethylhexanoate, and the like. The polymerization initiators may be used singly or two or more thereof may be used in combination. The amount of the polymerization initiator used can be set to 0.5 to 20 parts by mass and is preferably 1.0 to 16 parts by mass, based on 100 parts by mass of the raw material monomers (the total charge amount of the monomers).

At the time of producing the resin precursor (PA), as necessary, additives such as a polymerization inhibitor, a chain transfer agent, a photosensitizing agent, a filler, and a plasticizer may be used to an extent that the effect of the present invention is not impaired.

(Conversion Reaction from Resin Precursor (PA) to Copolymer (A))

The copolymer (A) can be produced by converting the structural unit (pb) contained in the resin precursor (PA) into the structural unit (b) in the presence of a basic catalyst and the solvent (PD). For example, a resin precursor composition containing the resin precursor (PA), a basic catalyst, and the solvent (PD) is held at a temperature of, for example, 0° C. to 150° C. for 0.1 to 10 hours. This causes a dealcoholization reaction and a decarboxylation reaction of the resin precursor (PA) to convert the structural unit (pb) contained in the resin precursor (PA) into the structural unit (b) and make it possible to generate a reaction solution containing the copolymer (A) and the solvent (PD).

### [Basic Catalyst]

The basic catalyst needs to be a catalyst capable of forming a double bond between the carbon atom to which R² bonds and the carbon atom to which R³ bonds in the group represented by formula (1) in the structural unit (pb) contained in the resin precursor (PA) and is not particularly limited. The basic catalyst may be used singly or two or more thereof may be used in combination.

As the basic catalyst, a basic catalyst having pKa (acidity constant) of 12.5 or more at 25° C. is preferably used. The basic catalyst having pKa of 12.5 or more at 25° C. includes basic catalysts having pKa of 12.5 or more in aqueous solutions and basic catalysts being too acidic to measure the pKa in an aqueous solution and having pKa of 12.5 or more in an aqueous solution, converted from the measurement result in an organic solvent.

The basic catalyst is preferably a compound represented by the following formula (6).

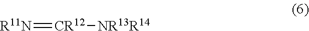

in formula (6), R¹¹, R¹³, and R¹⁴ are each independently a hydrogen atom or a hydrocarbon group having 1 to 20 carbon atoms, R¹² is a hydrogen atom, a hydrocarbon group having 1 to 20 carbon atoms, or a group represented by —N(R¹⁵)₂ (R¹⁵ in the formula is a hydrogen atom or a hydrocarbon group having 1 to 20 carbon atoms, and two R¹⁵'s may be the same as or different from each other), and out of R¹¹, R¹², R¹³, R¹⁴, and two R¹⁵'s, any two or more groups may bond together to form a cyclic structure.

The basic catalyst may be a compound represented by formula (7).

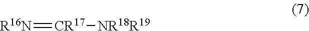

in formula (7), R¹⁶, R¹⁷, R¹⁸, and R¹⁹ are hydrocarbon groups, R¹⁶ and R¹⁹ bond together to form a cyclic structure, the sum of the numbers of the carbon atoms of R¹⁶ and R¹⁹ is 3 to 20, R¹⁷ and R¹⁸ bond together to form a cyclic structure, the sum of the numbers of the carbon atoms of R¹⁷ and R¹⁸ is 3 to 20.

In the compound represented by formula (7), the sum of the numbers of the carbon atoms of R¹⁶ and R¹⁹ forming the cyclic structure is 3 to 20 and preferably 3 to 10 from the viewpoint of ease of acquisition.

In the compound represented by formula (7), the sum of the numbers of the carbon atoms of R¹⁷ and R¹⁸ forming the cyclic structure is 3 to 20 and preferably 3 to 10 from the viewpoint of ease of acquisition.

As the basic catalyst, specifically, one or two or more kinds selected from 1,8-diazabicyclo[5.4.0]-7-undecene (DBU) (pKa 12.5), 1,5-diazabicyclo[4.3.0]-5-nonene (pKa 12.7), and 1,1,3,3-tetramethylguanidine (pKa 13.6) are preferably used, and in particular, from the viewpoint of the intensity of catalyst activity, compatibility with solvents, ease of acquisition and the like, 1,8-diazabicyclo[5.4.0]-7-undecene is particularly used.

The content of the basic catalyst is preferably 0.01 to 10 parts by mass, more preferably 0.05 to 5 parts by mass, and still more preferably 0.1 to 3 parts by mass, based on 100 parts by mass of the resin precursor (PA). When the content of the basic catalyst is 0.01 parts by mass or more, the reaction rate of converting the structural unit (pb) contained in the resin precursor (PA) into the structural unit (b) is likely to be sufficiently fast, which is preferable. When the content of the basic catalyst is 10 parts by mass or less, the influence of the basic catalyst can be curbed at the time of curing a photosensitive resin composition containing the copolymer (A) produced using the resin precursor composition.

### [Solvent (PD)]

Examples of the solvent (PD) include hydroxy group-containing solvents such as (poly)alkylene glycol monoalkyl ethers such as ethylene glycol monomethyl ether, ethylene glycol monoethyl ether, diethylene glycol monomethyl ether, diethylene glycol mono-n-butyl ether, triethylene glycol monomethyl ether, propylene glycol monomethyl ether, propylene glycol monoethyl ether, dipropylene glycol monomethyl ether, tripropylene glycol monoethyl ether, and 3-methoxy-1-butanol; hydroxy group-containing carboxylic acid esters such as methyl 2-hydroxypropionate, ethyl 2-hydroxypropionate, methyl 2-hydroxy-2-methylpropionate, ethyl 2-hydroxy-2-methylpropionate, hydroxyethyl acetate, and methyl 2-hydroxy-3-methylbutyrate; and diethylene glycol; and hydroxy group-free solvents such as (poly)alkylene glycol monoalkyl ether acetates such as ethylene glycol monomethyl ether acetate, ethylene glycol monoethyl ether acetate, propylene glycol monomethyl ether acetate, and propylene glycol monoethyl ether acetate; ethers such as diethylene glycol dimethyl ether, diethyleneglycol methylethyl ether, diethyleneglycol diethyl ether, and tetrahydrofuran; ketones such as methyl ethyl ketone, cyclohexanone, 2-heptanone, and 3-heptanone; esters such as methyl 3-methoxypropionate, methyl 3-ethoxypropionate, ethyl ethoxyacetate, 3-methyl-3-methoxybutyl acetate, 3-methyl-3-methoxy butyl propionate, ethyl acetate, n-butyl acetate, i-propyl acetate, i-butyl acetate, n-amyl acetate, i-amyl acetate, n-butyl propionate, ethyl butyrate, n-propyl butyrate, i-propyl butyrate, ethyl pyruvate, n-propyl pyruvate, methyl acetoacetate, ethyl acetoacetate, and ethyl 2-oxobutyrate; aromatic hydrocarbons such as toluene and xylene; and carboxylic acid amides such as N-methylpyrrolidone. N,N-dimethylformamide, and N,N-dimethylacetamide. The solvent (PD) may be used singly or two or more thereof may be used in combination.

Among these solvents (PD), from the viewpoint of ease of acquisition, the cost, and stability at the time of resist preparation, ethers are preferably used, and specifically, one or two or more selected from propylene glycol monomethyl ether acetate, diethylene glycol methyl ethyl ether, propylene glycol monomethyl ether, ethylene glycol monomethyl ether, and 3-methoxy-1-butanol are more preferably used.

The content of the solvent (PD) is preferably 30 to 1,000 parts by mass and more preferably 50 to 800 parts by mass, based on 100 parts by mass of the total of the components other than the solvent (PD) contained in the resin precursor composition. When the content of the solvent (PD) is 30 parts by mass or more, a stable polymerization reaction is possible, which is preferable. When the content of the solvent (PD) is 1,000 parts by mass or less, the viscosity of the resin precursor composition can be appropriately adjusted, which is preferable.

When the resin precursor (PA) contains the structural unit (c) and the structural unit (d), the conversion reaction for converting the structural unit (pb) into the structural unit (b) is preferably performed under a temperature condition that is lower than the temperature at which the dissociation rate of the blocked isocyanate group of the structural unit (d) having the blocked isocyanate group becomes 80% or more in 30 minutes. This is to suppress gelation resulting from the reaction between an isocyanate group, which is generated by dissociation of the blocked isocyanate group of the structural unit (d), and the hydroxy group of the structural unit (c) having a hydroxy group in the resin precursor composition during the conversion reaction. The temperature condition under which the conversion reaction is performed is more preferably lower than the temperature at which the dissociation rate of the blocked isocyanate group of the structural unit (d) becomes 80% or more in 30 minutes by 20° C. to 50° C.

Specifically, the temperature of the conversion reaction for converting the structural unit (pb) into the structural unit (b) can be set to 0° C. to 150° C. and is preferably between 50° C. to 120° C. and more preferably 60° C. to 100° C.

The holding time during which the resin precursor composition is held under the above-described temperature condition to perform the conversion reaction can be set to 0.1 to 10 hours and is preferably 0.3 to 5 hours and more preferably 0.5 to 3 hours. The holding time can be determined as appropriate, depending on the content of the structural unit (pb) contained in the resin precursor (PA) in the resin precursor composition, the content of the basic catalyst, the temperature condition, and the like.

The atmosphere in a reaction vessel for performing the conversion reaction can be, for example, an atmosphere containing air, dry air, nitrogen gas, helium gas, or the like, and is preferably a dry air or nitrogen gas atmosphere.

The pressure in the reaction vessel for performing the conversion reaction is not particularly limited, but is preferably normal pressure.

### (Reaction Path)

In the conversion reaction from the resin precursor (PA) into the copolymer (A), it is estimated that the structural unit (pb) contained in the resin precursor (PA) is converted into the structural unit (b) through a reaction path shown below.

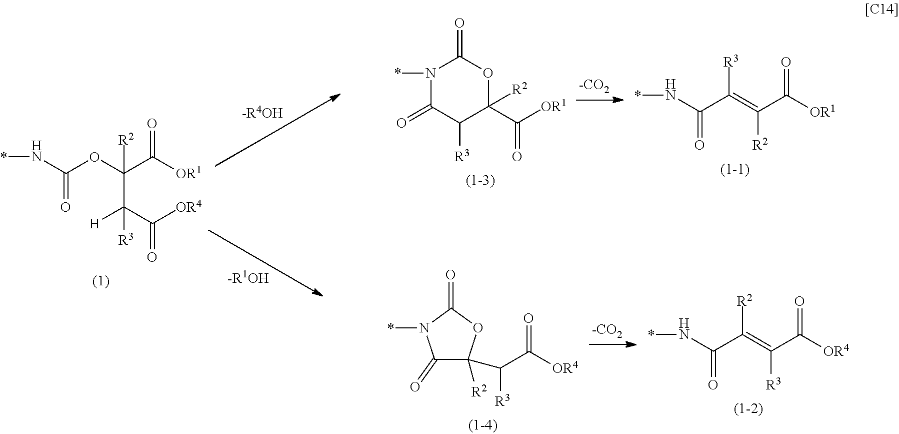

That is, in the structural unit (pb) having the group represented by formula (1) contained in the resin precursor (PA), a dealcoholization reaction between H of —NH— in a urethane bond and an ester moiety (—COOR¹ or —COOR⁴) occurs.

This forms a group having a heterocyclic ring represented by formula (1-3) and/or formula (1-4). The group having the heterocyclic ring represented by formula (1-3) is formed by the dealcoholization reaction (—R⁴OH) of an ester moiety containing R⁴ in the group represented by formula (1). The group having the heterocyclic ring represented by formula (1-4) is formed by the dealcoholization reaction (—R¹OH) of the ester moiety containing R¹ in the group represented by formula (1).

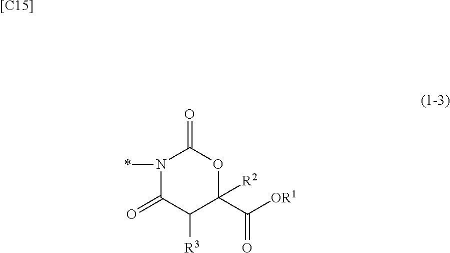

in formula (1-3), R¹, R², and R³ are the same as R¹, R², and R³ in formula (1), and * represents a linking site with a residue obtained by removing the group of formula (1-3) from the structural unit (pb).

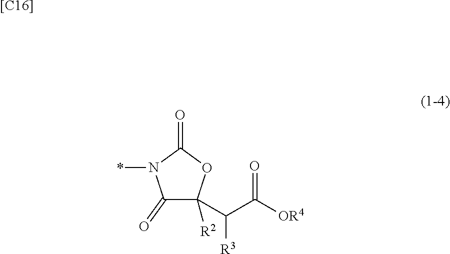

in formula (1-4), R², R³, and R⁴ are the same as R², R³, and R⁴ in formula (1), and * represents a linking site with a residue obtained by removing the group of formula (1-4) from the structural unit (pb).

Next, in the group having the heterocyclic ring represented by formula (1-3), decarboxylation (—CO₂) occurs in the heterocyclic moiety. This converts the group having the heterocyclic ring represented by formula (1-3) into the group represented by formula (1-1).

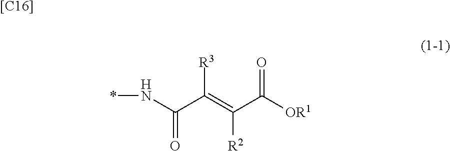

in formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group of formula (1-1) from the structural unit (b).

On the other hand, in the group having the heterocyclic ring represented by formula (1-4), decarboxylation (—CO₂) occurs in the heterocyclic moiety. This converts the group having the heterocyclic ring represented by formula (1-4) into the group represented by formula (1-2).

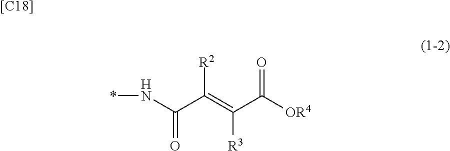

in formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group of formula (1-2) from the structural unit (b).

As a result of performing transition state calculation in the generation path of each product using wB97XD as a functional and 6−31+g (d) as a basis function in a density functional method, it is estimated that in the conversion reaction that converts the above-described structural unit (pb) into the structural unit (b), a reaction path of formula (1), formula (1-4), and formula (1-2) has a lower activation barrier than a reaction path of formula (1), formula (1-3), and formula (1-1) and becomes the main conversion route. Therefore, in the copolymer (A), it is estimated that a structural unit having the group represented by formula (1-2) and a structural unit having the group represented by formula (1-1) are present in a mixed manner and a larger number of the structural units having the group represented by formula (1-2) are present than the structural units having the group represented by formula (1-1).

### <Photosensitive Resin Composition and Photosensitive Coloring Composition>

A photosensitive resin composition of one embodiment contains the copolymer (A), a reactive diluent (B), a photopolymerization initiator (C), and a solvent (D). A photosensitive coloring composition of one embodiment further contains a coloring agent (E).

The content of the copolymer (A) in the photosensitive resin composition or the photosensitive coloring composition is preferably 10 parts by mass or more, more preferably 30 parts by mass or more, and still more preferably 60 parts by mass or more, based on 100 parts by mass of the total amount of the copolymer (A) and the reactive diluent (B). The content of the copolymer (A) in the photosensitive resin composition or the photosensitive coloring composition is preferably 90 parts by mass or less, more preferably 85 parts by mass or less, and still more preferably 80 parts by mass or less, based on 100 parts by mass of the total amount of the copolymer (A) and the reactive diluent (B). The combination of these lower limit values and upper limit values may be any combination. The content of the copolymer (A) in the photosensitive resin composition or the photosensitive coloring composition is preferably 10 to 90 parts by mass, more preferably 30 to 85 parts by mass, and still more preferably 60 to 80 parts by mass, based on 100 parts by mass of the total amount of the copolymer (A) and the reactive diluent (B). When the content of the copolymer (A) is 10 parts by mass or more, a photosensitive resin composition or photosensitive coloring composition enabling the formation of a cured product having superior low-temperature curability and having good solvent resistance can be obtained. When the content of the copolymer (A) is 90 parts by mass or less, the content of the reactive diluent (B) can be sufficiently ensured, and thus the strength and adhesion to a base material of the cured product are good.

### [Reactive Diluent (B)]

The reactive diluent (B) is a monomer having at least one ethylenically unsaturated bond as a polymerizable functional group in the molecule. The reactive diluent (B) may be a monofunctional monomer or a polyfunctional monomer having a plurality of polymerizable functional groups. When the reactive diluent (B) is contained, the viscosity of the photosensitive resin composition or the photosensitive coloring composition can be made to be within an appropriate range, depending on the application. In addition, when the photosensitive resin composition or the photosensitive coloring composition contains the reactive diluent (B), it is possible to form a cured product having good photocurability and good strength and adhesion to a base material. The reactive diluent (B) may be used singly or two or more thereof may be used in combination.

Examples of the monofunctional monomer used as the reactive diluent (B) include (meth)acrylates such as (meth)acrylamide, methylol (meth)acrylamide, methoxymethyl (meth)acrylamide, ethoxymethyl (meth)acrylamide, propoxymethyl (meth)acrylamide, butoxy methoxymethyl (meth)acrylamide, methyl (meth)acrylate, ethyl (meth)acrylate, butyl (meth)acrylate, 2-ethylhexyl (meth)acrylate, 2-hydroxyethyl (meth)acrylate, 2-hydroxypropyl (meth)acrylate, 4-hydroxy butyl (meth)acrylate, 2-phenoxy-2-hydroxypropyl (meth)acrylate, 2-(meth)acryloyloxy-2-hydroxypropyl phthalate, glycerin mono (meth)acrylate, tetrahydrofurfuryl (meth)acrylate, glycidyl (meth)acrylate, 2,2,2-trifluoroethyl (meth)acrylate, 2,2,3,3-tetrafluoropropyl (meth)acrylate, and half (meth)acrylate of phthalic acid derivatives; aromatic vinyl compounds such as styrene, α-methylstyrene, α-chloromethylstyrene, and vinyltoluene; carboxylic acid esters such as vinyl acetate and vinyl propionate; and the like. The monofunctional monomer may be used singly or two or more thereof may be used in combination.

Examples of the polyfunctional monomer used as the reactive diluent (B) include (meth)acrylates such as ethylene glycol di(meth)acrylate, diethylene glycol di(meth)acrylate, tetraethylene glycol di(meth)acrylate, propylene glycol di(meth)acrylate, polypropylene glycol di(meth)acrylate, butyleneglycol di(meth)acrylate, neopentyl glycol di(meth)acrylate, 1,6-hexane glycol di(meth)acrylate, trimethylol propane tri(meth)acrylate, glycerin di(meth)acrylate, pentaerythritol di(meth)acrylate, pentaerythritol tri(meth)acrylate, dipentaerythritol penta(meth)acrylate, dipentaerythritol hexa(meth)acrylate, 2,2-bis(4-(meth)acryloxy diethoxyphenyl) propane, 2,2-bis(4-(meth)acryloxypolyethoxyphenyl) propane, 2-hydroxy-3-(meth)acryloyloxypropyl (meth)acrylate, ethylene glycol diglycidyl ether di(meth)acrylate, diethyleneglycol diglycidyllether di(meth)acrylate, phthalic acid diglycidyl ester di(meth)acrylate, glycerin triacrylate, glycerin polyglycidyl ether poly(meth)acrylate, urethane (meth)acrylate (for example, a reaction product between tolylene diisocyanate, trimethylhexamethylene diisocyanate, hexamethylene diisocyanate, or the like and 2-hydroxyethyl (meth)acrylate), and tri(meth)acrylate of tris(hydroxyethyl) isocyanurate; aromatic vinyl compounds such as divinylbenzene, diallyl phthalate, and diallyl benzene phosphonate; dicarboxylic acid esters such as divinyl adipate; triallyl cyanurate, methylene bis(meth)acrylamide, condensation products between polyhydric alcohol and N-methylol (meth)acrylamide; and the like. The polyfunctional monomer may be used singly or two or more thereof may be used in combination.

Among these monomers, since a photosensitive resin composition or photosensitive 20) coloring composition having good photocurability can be obtained, the polyfunctional (meth)acrylate is preferably used as the reactive diluent (B), a polyfunctional (meth)acrylate that is trifunctional or higher is more preferably used, and trimethylolpropane tri(meth)acrylate, pentaerythritol tri(meth)acrylate, dipentaerythritol penta(meth)acrylate, or dipentaerythritol hexa(meth)acrylate is still more preferably used.

The content of the reactive diluent (B) in the photosensitive resin composition or the photosensitive coloring composition is preferably 10 parts by mass or more, more preferably 15 parts by mass or more, and still more preferably 30 parts by mass or more, based on 100 parts by mass of the total of the copolymer (A) and the reactive diluent (B). The content of the reactive diluent (B) in the photosensitive resin composition or the photosensitive coloring composition is preferably 90 parts by mass or less, more preferably 70 parts by mass or less, and still more preferably 60 parts by mass or less, based on 100 parts by mass of the total of the copolymer (A) and the reactive diluent (B). The combination of these lower limit values and upper limit values may be any combination. The content of the reactive diluent (B) in the photosensitive resin composition or the photosensitive coloring composition is preferably 10 to 90 parts by mass, more preferably 15 to 70 parts by mass, and still more preferably 30 to 60 parts by mass, based on 100 parts by mass of the total of the copolymer (A) and the reactive diluent (B). When the content of the reactive diluent (B) is 10 parts by mass or more, the effect of the reactive diluent (B) being contained becomes significant. When the content of the reactive diluent (B) is 90 parts by mass or less, since the content of the copolymer (A) can be sufficiently ensured, a photosensitive resin composition or photosensitive coloring composition having better low-temperature curability can be obtained.

### [Photopolymerization Initiator (C)]

The photopolymerization initiator (C) is not particularly limited, and examples thereof include 1-[9-ethyl-6-(2-methylbenzoyl)-9H-carbazol-3-yl-]-, -1-(O-acetyloxime); benzoin and its alkyl ethers such as benzoin, benzoin methyl ether, benzoin ethyl ether, and benzoin butyl ether; acetophenone compounds such as acetophenone, 2,2-dimethoxy-2-phenylacetophenone, 1,1-dichloroacetophenone, and 4′-(1-t-butyldioxy-1-methylethyl) acetophenone; 2-methyl-1-[4-(methylthio)phenyl]-2-morpholino-propane-1-one; 2-benzyl-2-dimethylamino-1-(4-morpholinophenyl) butanone-1; anthraquinone compounds such as 2-methylanthraquinone, 2-amylanthraquinone, 2-t-butylanthraquinone, and 1-chloroanthraquinone; xanthone; thioxanthone compounds such as thioxanthone, 2,4-dimethylthioxanthone, 2,4-diisopropyl thioxanthone, and 2-chlorothioxanthone; ketal compounds such as acetophenone dimethyl ketal, and benzyl dimethyl ketal; benzophenone compounds such as benzophenone, 4-(1-t-butyldioxy-1-20)methylethyl)benzophenone, and 3,3,4,4′-tetrakis(t-butyldioxycarbonyl)benzophenone; and acylphosphine oxide-based photopolymerization initiators. The photopolymerization initiator (C) may be used singly or two or more thereof may be used in combination.

The content of the photopolymerization initiator (C) in the photosensitive resin composition or the photosensitive coloring composition is preferably 0.1 parts by mass or more, more preferably 0.5 parts by mass or more, and still more preferably 1 part by mass or more, based on 100 parts by mass of the total amount of the copolymer (A) and the reactive diluent (B). The content of the photopolymerization initiator (C) in the photosensitive resin composition or the photosensitive coloring composition is preferably 30 parts by mass or less, more preferably 15 parts by mass or less, and still more preferably 10 parts by mass or less, based on 100 parts by mass of the total amount of the copolymer (A) and the reactive diluent (B). The combination of these lower limit values and upper limit values may be any combination. The content of the photopolymerization initiator (C) in the photosensitive resin composition or the photosensitive coloring composition is preferably 0.1 to 30 parts by mass, more preferably 0.5 to 15 parts by mass, and still more preferably 1 to 10 parts by mass, based on 100 parts by mass of the total amount of the copolymer (A) and the reactive diluent (B). When the content of the photopolymerization initiator (C) is 0.1 parts by mass or more, a photosensitive resin composition or photosensitive coloring composition having good photocurability can be obtained. When the content of the photopolymerization initiator (C) is 30 parts by mass or less, it is possible to prevent physical properties of a cured product of the photosensitive resin composition or the photosensitive coloring composition from being adversely affected by an excessive amount of the photopolymerization initiator (C).

### [Solvent (D)]

As the solvent (D), the same solvent as the solvent (PD) used to produce the copolymer (A) can be used. The solvent (D) in the photosensitive resin composition or the photosensitive coloring composition and the solvent (PD) used for producing the copolymer (A) may be the same as or different from each other.

The content of the solvent (D) in the photosensitive resin composition or the photosensitive coloring composition is preferably 30 parts by mass or more, and more preferably 50 parts by mass or more, based on 100 parts by mass of the total amount of the copolymer (A) and the reactive diluent (B). The content of the solvent (D) in the photosensitive resin composition or the photosensitive coloring composition is preferably 1,000 parts by mass or less, and more preferably 800 parts by mass or less, based on 100 parts by mass of the total amount of the copolymer (A) and the reactive diluent (B). The combination of these lower limit values and upper limit values may be any combination. The content of the solvent (D) in the photosensitive resin composition or the photosensitive coloring composition is preferably 30 to 1,000 parts by mass, and more preferably 50 to 800 parts by mass, based on 100 parts by mass of the total amount of the copolymer (A) and the reactive diluent (B). When the content of the solvent (D) is 30 parts by mass or more, the viscosity of the photosensitive resin composition or the photosensitive coloring composition can be made to be within an appropriate range. When the content of the solvent (D) is 1,000 parts by mass or less, the solvent (D) can be easily removed when the solvent (D) in a coating film formed by applying the photosensitive resin composition or the photosensitive coloring composition onto a base material is removed.

### [Coloring Agent (E)]

The photosensitive coloring composition may further contain a coloring agent (E). The photosensitive coloring composition containing the coloring agent (E) can be used as a material of color filters.

The coloring agent (E) is not particularly limited, as long as the coloring agent is dissolved or dispersed in the solvent (D), and examples thereof include dyes, pigments, and the like.

From the viewpoint of solubility in the solvent (D) and alkaline developing solutions, interaction with other components in the photosensitive coloring composition, heat resistance, and the like, it is preferable to use an acidic dye having an acid group such as a carboxy group or a sulfo group, a salt of an acidic dye with a nitrogen compound, a sulfonamide adduct of an acidic dye, or the like as the dyes.

Examples of such dyes include acid alizarin violet N; acid black 1, 2, 24, 48; acid blue 1, 7, 9, 25, 29, 40, 45, 62, 70, 74, 80, 83, 90, 92, 112, 113, 120, 129, 147; solvent blue 38, 44, 70; acid chrome violet K; acid Fuchsin; acid green 1, 3, 5, 25, 27, 50; acid orange 6, 7, 8, 10, 12, 50, 51, 52, 56, 63, 74, 95; acid red 1, 4, 8, 14, 17, 18, 26, 27, 29, 31, 34, 35, 37, 42, 44, 50, 51, 52, 57, 69, 73, 80, 87, 88, 91, 92, 94, 97, 103, 111, 114, 129, 133, 134, 138, 143, 145, 150, 151, 158, 176, 183, 198, 211, 215, 216, 217, 249, 252, 257, 260, 266, 274; acid violet 6B, 7, 9, 17, 19; acid yellow 1, 3, 9, 11, 17, 23, 25, 29, 34, 36, 42, 54, 72, 73, 76, 79, 98, 99, 111, 112, 114, 116; food yellow 3, derivatives thereof, and the like. Among these, an azo-based, xanthene-based, anthraquinone-based, or phthalocyanine-based acidic dye is preferable. The dyes can be used singly or two or more thereof can be used in combination.

Examples of the pigments include yellow pigments such as C.I, pigment yellow 1, 3, 12, 13, 14, 15, 16, 17, 20, 24, 31, 53, 83, 86, 93, 94, 109, 110, 117, 125, 128, 137, 138, 139, 147, 148, 150, 153, 154, 166, 173, 194, 214; orange pigments such as C.I, pigment orange 13, 31, 36, 38, 40, 42, 43, 51, 55, 59, 61, 64, 65, 71, 73; red pigments such as C.I, pigment red 9, 97, 105, 122, 123, 144, 149, 166, 168, 176, 177, 180, 192, 209, 215, 216, 224, 242, 254, 255, 264, 265; blue pigments such as C.I, pigment blue 15, 15:3, 15:4, 15:6, 60; violet pigments such as C.I, pigment violet 1, 19, 23, 29, 32, 36, 38; green pigments such as C.I, pigment green 7, 36, 58, 59; brown pigments such as C.I, pigment brown 23, 25; black pigments such as C.I, pigment black 1, 7, carbon black, titanium black, and iron oxide; and the like. The pigments can be used singly or two or more thereof can be used in combination.

The coloring agent (E) can be determined as appropriate, depending on, for example, the colors of desired coloring patterns (black matrices and pixels). The coloring agent (E) may be used singly or two or more thereof may be used in combination. When two or more coloring agents (E) are used, a combination of a dye and a pigment may be used.

When a pigment is used as the coloring agent (E), in order to improve pigment dispersibility, a known dispersing agent may be added to the photosensitive coloring composition. As the dispersing agent, it is preferable to use a polymer dispersing agent having excellent dispersion stability over time. Examples of polymer dispersing agents include a urethane-based dispersing agent, a polyethyleneimine-based dispersing agent, a polyoxyethylene alkyl ether-based dispersing agent, a polyoxyethylene glycol diester-based dispersing agent, a sorbitan aliphatic ester-based dispersing agent, and an aliphatic modified ester-based dispersing agent. As the polymer dispersing agent, commercially available products under product names such as EFKA (manufactured by EFKA CHEMICALS B.V.). Disperbyk (manufactured by BYK). Disparlon (manufactured by Kusumoto Chemicals. Ltd.), and SOLSPERSE (manufactured by Lubrizol) may be used. The content of the dispersing agent can be set as appropriate, depending on the type and amount of the pigment used as the coloring agent (E).

The content of the coloring agent (E) in the photosensitive coloring composition is preferably 3 parts by mass or more, more preferably 5 parts by mass or more, and still more preferably 10 parts by mass or more, based on 100 parts by mass of the total of the copolymer (A) and the reactive diluent (B). The content of the coloring agent (E) in the photosensitive coloring composition is preferably 80 parts by mass or less, more preferably 70 parts by mass or less, and still more preferably 60 parts by mass or less, based on 100 parts by mass of the total of the copolymer (A) and the reactive diluent (B). The combination of these lower limit values and upper limit values may be any combination. The content of the coloring agent (E) in the photosensitive coloring composition is preferably 3 to 80 parts by mass, more preferably 5 to 70 parts by mass, and still more preferably 10 to 60 parts by mass, based on 100 parts by mass of the total of the copolymer (A) and the reactive diluent (B). When the content of the coloring agent (E) is 3 parts by mass or more, the effect of the coloring agent (E) being contained becomes significant, and a photosensitive coloring composition suitable as a material of a coloring pattern of a color filter can be obtained. When the content of the coloring agent (E) is 80 parts by mass or less, the coloring agent (E) does not adversely affect the curability of the photosensitive coloring composition, and a photosensitive coloring composition having good low-temperature curability can be obtained.

### Other Components

With the resin composition of one embodiment, in addition to the copolymer (A), the solvent (D), the reactive diluent (B), and the photopolymerization initiator (C), and the coloring agent (E) optionally contained, known additives such as a coupling agent, a leveling agent, and a polymerization inhibitor may be blended, as necessary. The content of the additives is not particularly limited, as long as the effects of the present invention are not impaired.

### <Method for Producing Photosensitive Resin Composition and Photosensitive Coloring Composition>

The photosensitive resin composition of one embodiment can be produced by a method of mixing the copolymer (A), the reactive diluent (B), the photopolymerization initiator (C), and the solvent (D) using a known mixing device. The photosensitive coloring composition of one embodiment can be produced by a method of mixing the copolymer (A), the reactive diluent (B), the photopolymerization initiator (C), the solvent (D), and the coloring agent (E) using a known mixing device.

At the time of producing the photosensitive resin composition or the photosensitive coloring composition, as a raw material, the reaction solution containing the copolymer (A) obtained by converting the structural unit (pb) into the structural unit (b) and the solvent (PD) in the resin precursor composition may be used as it is. In this case, the solvent (PD) contained in the reaction solution can be used as a part or all of the solvent (D) contained in the photosensitive resin composition or the photosensitive coloring composition.

At the time of producing the photosensitive resin composition or the photosensitive coloring composition, the copolymer (A) isolated from the reaction solution containing the copolymer (A) and the solvent (PD) by a known method may also be used as a raw material.

Since the photosensitive resin composition or the photosensitive coloring composition contains the copolymer (A) having the structural unit (b) having the group represented by formula (1-1) or formula (1-2), the reactive diluent (B), and the photopolymerization initiator (C), when the composition is irradiated with light, the reactive diluent (B) polymerizes together with the ethylenically unsaturated group contained in the structural unit (b) of the copolymer (A), and good photocurability is exhibited.

Furthermore, when the photosensitive resin composition or the photosensitive coloring composition contains the copolymer (A) having the structural unit (c) having a hydroxy group and the structural unit (d) having a blocked isocyanate group, the composition has better low-temperature curability.

Due to these facts, when a cured product is formed using the photosensitive resin composition or the photosensitive coloring composition, the composition can be cured at a lower temperature compared with conventional resin compositions. Accordingly, for example, when a coating film formed on a base material is exposed and a baking treatment is then performed, since the crosslinking reaction sufficiently progresses even when the temperature of the baking treatment is low, the photosensitive resin composition or the photosensitive coloring composition enables the formation of a cured product having excellent solvent resistance. Therefore, when a cured product is formed using the photosensitive resin composition or the photosensitive coloring composition, the amount of energy required for heating to cure the composition is small. In addition, the use of the photosensitive resin composition or the photosensitive coloring composition makes it possible to form a cured product on a base material having low heat resistance such as a resin substrate without adversely affecting the base material. Furthermore, the photosensitive coloring composition enables the formation of a cured product exhibiting the original characteristics of the coloring agent (E) even when a poorly heat-resistant coloring agent is used as the coloring agent (E).

Since the photosensitive coloring composition can provide a cured product having excellent solvent resistance to be obtained even when the temperature of the baking treatment is low; the coloring agent (E) is less likely to be eluted. Therefore, it is also possible to increase the content of the coloring agent (E) in the photosensitive coloring composition. The photosensitive coloring composition containing a large amount of the coloring agent (E) enables the formation of a color filter having excellent color reproducibility by, for example, being used as a material of a coloring pattern of the color filter.

Since the copolymer (A) contained in the photosensitive resin composition or the photosensitive coloring composition has the structural unit (a) having an acid group, the photosensitive resin composition or the photosensitive coloring composition has good alkaline developability. Since such a photosensitive resin composition or photosensitive coloring composition has excellent alkaline developability, for example, when the composition is applied onto a base material to form a coating film, the coating film is exposed through a photomask corresponding to a predetermined pattern shape, an unexposed portion is developed with an alkaline aqueous solution, and a baking treatment is then performed at a sufficiently low temperature, a cured product having a predetermined pattern shape and excellent solvent resistance can be formed.

The photosensitive resin composition and the photosensitive coloring composition can be suitably used as a material for color filters.

Due to these facts, the photosensitive resin composition and the photosensitive coloring composition are very useful as a material for forming members of image display elements, for example, color filter pixels, black matrices, a color filter protective film, a photo spacer, a liquid crystal alignment protrusion, a micro lens, and a touch panel insulating film.

### <Resin Cured Film>

A resin cured film of one embodiment comprises a cured product of the photosensitive resin composition or the photosensitive coloring composition.

The resin cured film can be produced by, for example, a method of applying the photosensitive resin composition or the photosensitive coloring composition onto a base material, removing the solvent (D) by volatilization to form a coating film, exposing and photocuring the coating film, and then performing a baking treatment.

When a resin cured film having a predetermined pattern shape is formed, for example, the following method can be used. In other words, the photosensitive resin composition or the photosensitive coloring composition is applied onto a base material, and the solvent (D) is removed by volatilization to form a coating film. Next, the coating film is exposed through a photomask having a predetermined pattern shape, and the exposed portion is photocured. Next, the unexposed portion of the coating film is developed with an alkaline aqueous solution. After that, a baking treatment is performed on the developed coating film, thereby forming a resin cured film having a predetermined pattern shape.

At the time of producing the resin cured film, known methods can be used as a method for applying the photosensitive resin composition or the photosensitive coloring composition, a method for exposing the coating film, and a developing method.

The conditions of the baking treatment performed at the time of producing the resin cured film can be determined as appropriate, depending on the composition of the photosensitive resin composition or the photosensitive coloring composition, the film thickness of the coating film, the material of the base material, and the like. The baking treatment can be performed at a temperature of, for example, 70° C. to 250° C. When the temperature of the baking treatment is 70° C. or higher, the blocked isocyanate group of the structural unit (d) having a blocked isocyanate group contained in the copolymer (A) in the photosensitive resin composition or the photosensitive coloring composition sufficiently dissociates. Therefore, an isocyanate group is generated and cross-links with the hydroxy group of the structural unit (c) having a hydroxy group. When the structural unit (d) has a carboxylic acid alkyl ester structure, the formation of a cross-link by ester exchange between the carboxylic acid alkyl ester structure and the hydroxy group occurs. As a result, a good degree of curing can be obtained, and a cured product having excellent solvent resistance can be obtained. When the structural unit (d) has a carboxylic acid alkyl ester structure, both a deblocking reaction and an ester exchange reaction can occur, and any of the reactions can be made to preferentially progress by adjusting the baking temperature. The temperature of the baking treatment is preferably 75° C. or higher, and more preferably 80° C. or higher. When the temperature of the baking treatment is 250° C. or lower, it is a condition that poorly heat-resistant materials can withstand and the discoloration of the photosensitive resin composition or the photosensitive coloring composition can be curbed, which is preferable. The photosensitive resin composition and the photosensitive coloring composition have good low-temperature curability. Therefore, the temperature of the baking treatment can be set to 160° C. or lower, depending on the heat resistance of the base material on which the resin cured film is formed, and for example, when a resin substrate is used as the base material, the temperature may be set to 150° C. or lower, may be set to 120° C. or lower, or may be set to 100° C. or lower.

The baking treatment performed at the time of producing the resin cured film can be performed, for example, for 10 minutes to 4 hours, and preferably 20 minutes to 2 hours, which can be determined as appropriate, depending on the composition of the photosensitive resin composition or the photosensitive coloring composition, the temperature in the baking treatment, the film thickness of the coating film, and the like.

The resin cured film comprises a cured product of the photosensitive resin composition or the photosensitive coloring composition. Therefore, the resin cured film can be produced using a method of performing a baking treatment at a low temperature and furthermore has excellent solvent resistance.

### <Color Filter>

A color filter of one embodiment includes coloring patterns comprising a cured product of the photosensitive coloring composition. The color filter preferably has coloring patterns comprising a cured product of the photosensitive coloring composition containing 10 to 90 parts by mass of the copolymer (A), 10 to 90 parts by mass of the reactive diluent (B), 0.1 to 30 parts by mass of the photopolymerization initiator (C), 30 to 1,000 parts by mass of the solvent (D), and 3 to 80 parts by mass of the coloring agent (E), based on 100 parts by mass of the total of the copolymer (A) and the reactive diluent (B).

The color filter may include, for example, a substrate, RGB pixels formed thereon, black matrices formed at the boundaries between the respective pixels, and a protective film formed on the pixels and the black matrices.

In the color filter, the pixels and the black matrices are coloring patterns which comprise a cured product of the photosensitive coloring composition. In the color filter, as configurations other than the material of the pixels and the black matrices, known configurations can be used.

The substrate used for the color filter is not particularly limited, and a glass substrate, a silicon substrate, a polycarbonate substrate, a polyester substrate, a polyamide substrate, a polyamideimide substrate, a polyimide substrate, an aluminum substrate, a printed circuit board, an array substrate, and the like can be used as appropriate, depending on applications.

### <Method for Producing Color Filter>

Next, an exemplary method for producing the color filter will be described. First, coloring patterns are formed on a substrate. Specifically, on the substrate, a coloring pattern that will become black matrices formed at the boundaries between the pixels and a coloring pattern that will become the RGB pixels are sequentially formed by the following method.

The coloring patterns can be formed by a photolithography method. Specifically, the photosensitive coloring composition is applied onto the substrate to form a coating film. After that, the coating film is exposed through a photomask having a predetermined pattern shape, and the exposed portion is photocured. Next, the unexposed portion of the coating film is developed with an alkaline aqueous solution. Thereafter, a baking treatment is performed on the developed coating film, thereby forming a coloring pattern having a predetermined pattern shape.

The method for applying the photosensitive coloring composition is not particularly limited, and known methods such as a screen printing method, a roll coating method, a curtain coating method, a spray coating method, and a spin coating method can be used.

After the photosensitive coloring composition is applied onto the substrate, as necessary, the solvent (D) contained in the coating film may be removed by volatilization by heating the substrate using a heating unit such as a circulating oven, an infrared heater, or a hot plate. The conditions for heating the substrate to remove the solvent (D) are not particularly limited, and can be set as appropriate, depending on the material of the substrate, the composition of the photosensitive coloring composition, the film thickness of the coating film, and the like. The substrate can be heated, for example, at a temperature of 50° C. to 120° C. for 30 seconds to 30 minutes.

Next, the coating film thus formed is irradiated with, for example, active energy rays such as ultraviolet rays and excimer laser light through a negative type photomask and partially exposed, and the exposed portion is photocured. The amount of the active energy rays used to irradiate the coating film may be selected as appropriate, depending on the composition of the photosensitive coloring composition and the like, and can be set to, for example, 30 to 2000 mJ/cm². A light source used for exposure is not particularly limited, and a low-pressure mercury lamp, a medium-pressure mercury lamp, a high-pressure mercury lamp, a xenon lamp, a metal halide lamp, or the like can be used.

The alkaline aqueous solution used for developing the coating film is not particularly limited, and for example, aqueous solutions of an inorganic alkaline compound such as sodium carbonate, potassium carbonate, calcium carbonate, sodium hydroxide, or potassium hydroxide; aqueous solutions of an amine compound such as ethylamine, diethylamine, or dimethylethanolamine; aqueous solutions of a quaternary ammonium salt such as a sulfate, hydrochloride or p-toluenesulfonate of tetramethylammonium; aqueous solutions of an aniline compound or a salt thereof such as 3-methyl-4-amino-N,N-diethylaniline, 3-methyl-4-amino-N-ethyl-N-β-hydroxyethylaniline, 3-methyl-4-amino-N-ethyl-N-β-methanesulfonamide ethylaniline, 3-methyl-4-amino-N-ethyl-N-β-methoxyethyl aniline, and a sulfate, hydrochloride or p-toluenesulfonate thereof; aqueous solutions of a p-phenylenediamine compound or a salt thereof; and the like can be used. As necessary, additives such as an antifoaming agent and a surfactant may be added to the alkaline aqueous solution.

After the coating film is developed using the alkaline aqueous solution, the coating film is preferably washed with water and dried.

The conditions of the baking treatment performed at the time of producing the color filter can be determined as appropriate, depending on the composition of the photosensitive coloring composition, the film thickness of the coating film, the material of the substrate, and the like. The temperature of the baking treatment can be set to, for example, 70° C. to 210° C. When the baking temperature is 70° C. or higher, good curability can be obtained, and a cured product having excellent solvent resistance can be obtained. The temperature of the baking treatment is preferably 75° C. or higher, and more preferably 80° C. or higher. When the temperature of the baking treatment is 210° C. or lower, a poorly heat-resistant material, such as a substrate having low heat resistance, can be used as the material for the color filter, which is preferable.

In a case where a conventional photosensitive coloring composition is used to form a coloring pattern of a color filter, when the temperature of the baking treatment is set to 200° C. or lower, the solvent resistance of the coloring pattern is insufficient. On the other hand, since the photosensitive coloring composition of one embodiment has good low-temperature curability, the temperature of the baking treatment can be lowered compared with the temperature in the case of using a conventional photosensitive coloring composition while the solvent resistance of the coloring pattern is ensured. Specifically, the temperature of the baking treatment can be set to 160° C. or lower, depending on the heat resistance of the base material on which the resin cured film is formed, and for example, when a coloring pattern is formed using a resin substrate as the base material, the temperature may be set to 150° C. or lower, may be set to 120° C. or lower, and may be set to 100° C. or lower.

The baking treatment performed at the time of producing the color filter can be performed for, for example, 10 minutes to 4 hours, and preferably 20 minutes to 2 hours, and can be determined as appropriate, depending on the composition of the photosensitive coloring composition, the temperature of the baking treatment, the film thickness of the coating film, and the like.

The photosensitive coloring composition has good photocurability and low-temperature curability. Therefore, when a coloring pattern is formed using the photosensitive coloring composition of one embodiment, the time of the baking treatment can be shortened, and the color filter can be efficiently formed relative to forming a coloring pattern using a conventional photosensitive coloring composition, provided that the temperature of the baking treatment is the same.

A coloring pattern that will become RGB pixels and a coloring pattern that will become black matrices formed at the boundaries between the pixels are formed using the above-described method for producing a coloring pattern, and a protective film is then formed on the coloring patterns (the RGB pixels and the black matrices).

The method of producing the protective film is not particularly limited, and the protective film may be formed using the photosensitive resin composition of one embodiment or may be formed, using a known material and a known method.

The color filter can be obtained by the above steps.

The color filter has a coloring pattern comprising a cured product of the above-described photosensitive coloring composition. Therefore, the coloring pattern in the color filter can be formed by a method in which the baking treatment is performed at a low temperature. Accordingly, the amount of energy required for the baking treatment can be reduced.

In addition, as the coloring agent (E) contained in the photosensitive coloring composition used as a material of the color filter, a poorly heat-resistant coloring agent can be used. Therefore, choices of available coloring agents (E) can be increased. Accordingly, it is possible to form, for example, a color filter that contains a poorly heat-resistant coloring agent (E) and has a coloring pattern exhibiting the original characteristics of the poorly heat-resistant coloring agent (E).

Furthermore, the coloring pattern in the color filter can be formed on a poorly heat-resistant base material such as a resin substrate without causing any trouble on the base material. Accordingly, choices of available base materials can be increased. For example, the color filter can be formed on a poorly heat-resistant base material, such as a resin substrate, and a display can be thus made to be flexible. In addition, the coloring pattern in the color filter has excellent solvent resistance and thus undergoes less color change.

A case in which a coloring pattern is produced using the method in which the photosensitive coloring composition containing the photopolymerization initiator (C) is used and the photosensitive coloring composition is photocured has been exemplified, although a coloring pattern comprising a cured product of the photosensitive coloring composition containing the copolymer (A) may be formed using, for example, a method in which a photosensitive coloring composition containing a curing accelerator and a known epoxy resin is used in place of the photopolymerization initiator (C) contained in the photosensitive coloring composition is used, and the composition is applied onto a substrate by an inkjet method and then heated.

### <Image Display Element>

An image display element of one embodiment includes a color filter. In the image display element, as configurations other than the color filter, known configurations can be used. Specific examples of the image display element include, for example, solid-state imaging elements such as liquid crystal display elements, organic EL display elements, CCD elements, CMOS elements, and the like.

Configurations other than the color filter in the image display element can be produced by a known method. For example, when a liquid crystal display element is produced as the image display element, the liquid crystal display element can be produced using the following method. First, a color filter is formed on a substrate using the above-described method. After that, an electrode, a spacer, and the like are sequentially formed on the substrate having the color filter. Next, an electrode and the like are formed on another substrate, and this substrate is disposed to face the substrate having the color filter and pasted together. After that, a predetermined amount of liquid crystal is injected between the facing substrates and sealed.

The image display element includes the color filter having excellent solvent resistance and thus undergoes less color changes.

### EXAMPLES

Hereinafter, the present invention will be more specifically described with Examples and Comparative Examples, but the present invention is not limited to Examples below.

Synthesis examples of the copolymer (A) will be shown below.

### Example 1 (Synthesis Example 1)

### (Synthesis of Resin Precursor (PA))

As the solvent (PD), 268.47 g of propylene glycol monomethyl ether (manufactured by Tokyo Chemical Industry Co., Ltd.) was put into a flask including a stirring device, a dropping funnel, a condenser, a thermometer, and a gas inlet tube, stirred while the inside of the flask was substituted with a nitrogen gas, and heated to 78° C.

Next, 17.2 g (20 mol %) of methacrylic acid as a monomer (m-a), 49.7 g (15 mol %) of 2-[(diethyl malate)carbonylamino]ethyl acrylate as a monomer (m-pb), 19.5 g (15 mol %) of 2-hydroxyethyl methacrylate as a monomer (m-c), 90.3 g (30 mol %) of a reaction product between 2-isocyanatoethyl acrylate and diethyl malonate as a monomer (m-d), 36.8 g (20 mol %) of 2-ethylhexylacrylate as a monomer (m-e), 64.0 g (30 parts by mass based on 100 parts by mass of the total of the monomer components) of propylene glycol monomethyl ether as a solvent (PD), and 34.2 g (16 parts by mass based on 100 parts by mass of the total of the monomer components) of 2,2′-azobis(2,4-dimethylvalenitrile) (manufactured by FUJIFILM Wako Pure Chemical Corporation) as a polymerization initiator were mixed together to prepare a raw material monomer solution.

The total amount of the prepared raw material monomer solution was added dropwise to the solvent (PD) in the normal-pressure flask made into a nitrogen gas atmosphere using a dropping funnel over 1 hour. After the dropwise addition was completed, the solution in the flask was subjected to a polymerization reaction at 78° C. for 3 hours with stirring to obtain a liquid containing a resin precursor (PA) and the solvent (PD).

(Preparation of Resin Precursor Composition) 0.5 g (0.2 parts by mass based on 100 parts by mass of the total of the monomer components of the resin precursor (PA)) of hydroquinone monomethylether (MEHQ) as a polymerization inhibitor and 0.5 g (0.2 parts by mass based on 100 parts by mass of the total of the monomer components of the resin precursor (PA)) of 1,8-diazabicyclo[5.4.0]-7-undecene (DBU) (manufactured by San-Apro Ltd.) as a basic catalyst were charged into the solution containing the resin precursor (PA) and the solvent (PD) in the normal-pressure flask made into a nitrogen gas atmosphere to obtain a resin precursor composition.

### (Synthesis of Copolymer (A))

The resin precursor composition was held with stirring in the normal-pressure flask made into a nitrogen gas atmosphere at 78° C. for 300 minutes to convert the structural unit (pb) having the group represented by formula (1) contained in the resin precursor (PA) into the structural unit (b) having the group represented by formula (1-1) or formula (1-2). As a result, a reaction solution containing the copolymer (A) and the solvent (PD) was obtained. The weight average molecular weight, ethylenically unsaturated group equivalent, and acid value of the copolymer (A) were measured by the above-described methods and shown in Table 1. The blocked isocyanate group equivalent and hydroxy group equivalent of the copolymer (A) were calculated and shown in Table 1.

To the reaction solution containing the copolymer (A) and the solvent (PD) thus obtained, propylene glycol monomethyl ether acetate (manufactured by Tokyo Chemical Industry Co., Ltd.) was added as the solvent (D) so that the components other than the solvent reached 35 mass % to obtain a solution of the copolymer (A) of Example 1.

### Examples 2 to 9 (Synthesis Examples 2 to 9)

Solutions of copolymers (A) of Examples 2 to 9 were obtained in the same manner as in Example 1 except that monomers and amounts blended shown in Table 1 were used. The weight average molecular weights, ethylenically unsaturated group equivalents, and acid values of the copolymers (A) of Examples 2 to 9 were measured by the above-described methods and shown in Table 1. The blocked isocyanate group equivalents and hydroxy group equivalents of the copolymers (A) of Examples 2 to 9 were calculated and shown in Table 1.

### Comparative Example 1 (Comparative Synthesis Example 1)

As the solvent (PD), 273.6 g of propylene glycol monomethyl ether (manufactured by Tokyo Chemical Industry Co., Ltd.) was put into a flask including a stirring device, a dropping funnel, a condenser, a thermometer, and a gas inlet tube, stirred while the inside of the flask was substituted with a nitrogen gas, and heated to 78° C.

Next, 66.2 g (20 mol %) of 2-[(diethyl malate)carbonylamino]ethyl acrylate as a monomer (m-pb), 39.0 g (30 mol %) of 2-hydroxyethyl methacrylate as a monomer (m-c), 31.5 g (10 mol %) of 2-[(3,5-dimethylpyrazolyl)carbonylamino)ethyl methacrylate as a monomer (m-d), 73.6 g (40 mol %) of 2-ethylhexylacrylate as a monomer (m-e), 63.1 g (30 parts by mass based on 100 parts by mass of the total of the monomer components) of propylene glycol monomethyl ether as a solvent (PD), and 33.7 g (16 parts by mass based on 100 parts by mass of the total of the monomer components) of 2,2′-azobis(2,4-dimethylvalenitrile) (manufactured by FUJIFILM Wako Pure Chemical Corporation) as a polymerization initiator were mixed together to prepare a raw material monomer solution.

The total amount of the prepared raw material monomer solution was added dropwise to the solvent (PD) in the normal-pressure flask made into a nitrogen gas atmosphere using a dropping funnel over 1 hour. After the dropwise addition was completed, the solution in the flask was subjected to a polymerization reaction at 78° C. for 3 hours with stirring to obtain a liquid containing a resin precursor (PA) and the solvent (PD).

### (Preparation of Resin Precursor Composition)

0.2 g (0.1 parts by mass based on 100 parts by mass of the total of the monomer components of the resin precursor (PA)) of 1,8-diazabicyclo[5.4.0]-7-undecene (DBU) (manufactured by San-Apro Ltd.) as a basic catalyst was charged into the solution containing the resin precursor (PA) and the solvent (PD) in the normal-pressure flask made into a nitrogen gas atmosphere to obtain a resin precursor composition.

### (Synthesis of Copolymer)

10 g (10 mol based on 100 mol of the total of the monomers used to synthesize the resin precursor (PA)) of succinic anhydride (SA) (manufactured by New Japan Chemical Co., Ltd.) and 0.9 g (0.4 parts by mass based on 100 parts by mass of the total of the monomers used to synthesize the resin precursor (PA) and the succinic anhydride) of lithium naphthenate (manufactured by Toei Chemical Industry Co., Ltd.) as a catalyst were charged into the resin precursor composition, held at 78° C. for 300 minutes to be subjected to an addition reaction, and the structural unit (pb) having the group represented by formula (1) contained in the resin precursor (PA) was converted into the structural unit (b) having the group represented by formula (1-1) or formula (1-2). As a result, a reaction solution containing a copolymer (cA) and the solvent (PD) was obtained. The weight average molecular weight, ethylenically unsaturated group equivalent, and acid value of the copolymer (cA) were measured by the above-described methods and shown in Table 1. The blocked isocyanate group equivalent and hydroxy group equivalent of the copolymer (cA) were calculated and shown in Table 1.

To the reaction solution containing the copolymer (cA) and the solvent (PD) thus obtained, propylene glycol monomethyl ether acetate (manufactured by Tokyo Chemical Industry Co., Ltd.) was added as the solvent (D) so that the components other than the solvent reached 35 mass % to obtain a solution of the copolymer (cA) of Comparative Example 1.

### Comparative Example 2 (Comparative Synthesis Example 2)

As the solvent (PD), 241.2 g of propylene glycol monomethyl ether (manufactured by Tokyo Chemical Industry Co., Ltd.) was put into a flask including a stirring device, a dropping funnel, a condenser, a thermometer, and a gas inlet tube, stirred while the inside of the flask is substituted with a nitrogen gas, and heated to 78° C.

Next, 15.5 g (18 mol %) of methacrylic acid as a monomer (m-a), 18.2 g (14 mol %) of 2-hydroxyethyl methacrylate as a monomer (m-c), 60.2 g (20 mol %) of a reaction product between 2-isocyanatoethyl acrylate and diethyl malonate as a monomer (m-d), 88.3 g (48 mol %) of 2-ethyl hexyl acrylate as a monomer (m-e), 54.7 g (30) parts by mass based on 100 parts by mass of the total of the monomer components) of propylene glycol monomethyl ether as a solvent (PD), and 29.2 g (16 parts by mass based on 100 parts by mass of the total of the monomer components) of 2.2″-azobis(2,4-dimethylvalenitrile) (manufactured by FUJIFILM Wako Pure Chemical Corporation) as a polymerization initiator were mixed together to prepare a raw material monomer solution.

The total amount of the prepared raw material monomer solution was added dropwise to the solvent (PD) in the normal-pressure flask made into a nitrogen gas atmosphere using a dropping funnel over 1 hour. After the dropwise addition was completed, the solution in the flask was subjected to a polymerization reaction at 78° C. for 3 hours with stirring to obtain a reaction solution containing a copolymer (cA) and the solvent (PD). The weight average molecular weight, ethylenically unsaturated group equivalent, and acid value of the copolymer (cA) were measured by the above-described methods and shown in Table 1. The blocked isocyanate group equivalent and hydroxy group equivalent of the copolymer (cA) were calculated and shown in Table 1.

To the reaction solution containing the copolymer (cA) and the solvent (PD) thus obtained, propylene glycol monomethyl ether acetate (manufactured by Tokyo Chemical Industry Co., Ltd.) was added as the solvent (D) so that the components other than the solvent reached 35 mass % to obtain a solution of the copolymer (cA) of Comparative Example 2.

TABLE 1

| | | | | | | | | | | | | | Comp. | Comp. |
|---|---|---|---|---|---|---|---|---|---|---|---|---|---|---|
| | | | | | | | | | | | | | Ex. 1 | Ex. 2 |
| | | | | Ex. 1 | Ex. 2 | Ex. 3 | Ex. 4 | Ex. 5 | Ex. 6 | Ex. 7 | Ex. 8 | Ex. 9 | Comp. | Comp. |
| | | | | Syn. | Syn. | Syn. | Syn. | Syn. | Syn. | Syn. | Syn. | Syn. | Syn. | Syn. |
| | | | Unit | Ex. 1 | Ex. 2 | Ex. 3 | Ex. 4 | Ex. 5 | Ex. 6 | Ex. 7 | Ex. 8 | Ex. 9 | Ex. 1 | Ex. 2 |
| Mono- | m-a | MAA | mol % | 20 | 20 | 20 | 20 | 20 | 10 | 30 | 20 | 20 | 0 | 18 |
| mers | m-pb | A01-MDE | | 15 | 15 | 20 | 20 | 30 | 15 | 15 | 10 | 30 | 20 | 0 |
| | m-c | HEMA | | 15 | 0 | 20 | 20 | 0 | 15 | 15 | 15 | 15 | 30 | 14 |
| | | 4HBA | | 0 | 10 | 0 | 0 | 0 | 0 | 0 | 0 | 0 | 0 | 0 |
| | m-d | A01-DEM | | 30 | 20 | 0 | 0 | 30 | 30 | 30 | 30 | 30 | 0 | 20 |
| | | M01-BP | | 0 | 0 | 20 | 0 | 0 | 0 | 0 | 0 | 0 | 10 | 0 |
| | | M01-BM | | 0 | 0 | 0 | 20 | 0 | 0 | 0 | 0 | 0 | 0 | 0 |
| | m-e | ZEHA | | 20 | 35 | 20 | 20 | 20 | 30 | 10 | 25 | 5 | 40 | 48 |

| Total | | | 100 | 100 | 100 | 100 | 100 | 100 | 100 | 100 | 100 | 100 | 100 |
|---|---|---|---|---|---|---|---|---|---|---|---|---|---|
| Addition reaction | SA | mol*¹ | — | — | — | — | — | — | — | — | — | 10 | — |
| Polymerization | MEHQ | Parts by | 0.2 | 0.2 | 0.2 | 0.2 | 0.2 | 0.2 | 0.2 | 0.2 | 0.2 | — | — |
| inhibitor | | mass*² | | | | | | | | | | | |
| Basic catalyst | DBU | Parts by | 0.2 | 0.2 | 0.2 | 0.2 | 0.2 | 0.2 | 0.2 | 0.2 | 0.2 | 0.1 | — |
| | | mass*² | | | | | | | | | | | |

| | | | | | | | | | | | | |
|---|---|---|---|---|---|---|---|---|---|---|---|---|
| Weight average molecular | | 7600 | 6900 | 8400 | 7800 | 7400 | 3200 | 8100 | 7500 | 8200 | 8100 | 6000 |
| weight | | | | | | | | | | | | |
| Ethylenically unsaturated | g/mol | 3002 | 2895 | 2240 | 2053 | 1713 | 3138 | 2864 | 4347 | 1656 | 2140 | 0 |
| group equivalent | | | | | | | | | | | | |
| Acid value | KOHmg/g | 62.5 | 65 | 66.3 | 72.4 | 63.6 | 34.7 | 93.4 | 61.5 | 65.8 | 36.8 | 55.7 |
| Blocked isocyanate | g/mol | 413 | 597 | 1232 | 1129 | 471 | 432 | 394 | 398 | 455 | 2354 | 528 |
| group equivalent | | | | | | | | | | | | |
| Hydroxy group equivalent | g/mol | 1651 | 2388 | 1232 | 1129 | 0 | 1726 | 1575 | 1594 | 1821 | 1177 | 1510 |
| Storage stability | | 11% | 13% | 16% | 5% | 6% | 9% | 13% | 11% | 12% | 12% | 7% |

*¹Number of moles based on 100 moles of total of monomers
*²Parts by mass based on 100 parts by mass of total of monomers

As the compounds shown in Table 1, the following were used, respectively.
MAA: Methacrylic acid (manufactured by Kuraray Co., Ltd.)
AOI-MDE: KARENZ (trademark) AOI-MDE, 2-[(diethyl malate)carbonylamino]ethyl acrylate (manufactured by Showa Denko K.K.)
AOI-DEM: KARENZ (trademark) AOI-DEM, reaction product between 2-isocyanatoethyl acrylate and diethyl malonate (manufactured by Showa Denko K.K.)
MOI-BP: KARENZ (trademark) MOI-BP, 2-[(3,5-dimethylpyrazolyl)carbonylamino)ethyl methacrylate (manufactured by Showa Denko K.K.)
MOI-BM: KARENZ (trademark) MOI-BM, 2-[(methyl ethyl ketoxime)carbonylamino]ethyl methacrylate (manufactured by Showa Denko K.K.)
HEMA: 2-Hydroxyethyl methacrylate (manufactured by Nippon Shokubai Co., Ltd.)
4HBA: 4-Hydroxy butyl acrylate (manufactured by Osaka Organic Chemical Industry Ltd.)
2EHA: 2-Ethylhexylacrylate (manufactured by Toagosei Co., Ltd.)
SA: Succinic anhydride (manufactured by New Japan Chemical Co., Ltd.)
DBU: 1,8-Diazabicyclo[5.4.0]-7-undecene (manufactured by San-Apro Ltd.)

### [Evaluation of Storage Stability]

In a 20 mL sample bottle, 10 mL of the solution of copolymer (A) obtained in Example 1 was measured, sealed, and stored under a condition of 5° C. for 3 months. The weight average molecular weight of the sample after storage was measured, and the increase rate of weight average molecular weight was calculated according to the following formula. For the solutions of the copolymer (A) or the copolymer (cA) obtained in Examples 2 to 9 and Comparative Examples 1 and 2 as well, the increase rates of weight average molecular weight were calculated. The increase rates of weight average molecular weight are shown in Table 1. When the increase rate is 20% or less, storage stability is good.

Increase rate of weight average molecular weight (%)=(weight average molecular weight after storage−weight average molecular weight before storage)/weight average molecular weight before storage×100

### Examples 10 to 18 and Comparative Examples 3 and 4

The copolymer (A) of each of Synthesis Examples 1 to 9 or the copolymer (cA) of each of Comparative Synthesis Examples 1 and 2, dipentaerythritol hexaacrylate (manufactured by Toagosei Co., Ltd.) as the reactive diluent (B), 1-[9-ethyl-6-(2-methylbenzoyl)-9H-carbazol-3-yl-]-, -1-(O-acetyloxime) (manufactured by BASF) as the photopolymerization initiator (C), a mixture of propylene glycol monomethyl ether acetate and propylene glycol monomethyl ether (338 parts by mass and 257 parts by mass, respectively) as the solvent (D), and Valifast Blue 2620 (phthalocyanine-based dye, manufactured by Orient Chemical Industries Co., Ltd.) as the coloring agent (E) shown in Table 2 were each mixed in a proportion shown in Table 2 to prepare photosensitive coloring compositions of Examples 10 to 18 and Comparative Examples 3 and 4.

The amounts of the copolymer (A) or (cA) blended shown in Table 2 do not include the amount of the solvent (D). The amounts of the solvent (D) blended shown in Table 2 are the sums of the amount of the solvent contained in each of the solutions of the copolymer (A) or (cA) obtained in Examples 1 to 9 and Comparative Examples 1 and 2 and the amount of the solvent added at the time of preparing the photosensitive coloring composition.

TABLE 2

| | | | | | | | | | | | | Comp. | Comp. |
|---|---|---|---|---|---|---|---|---|---|---|---|---|---|
| | | | Ex. 10 | Ex. 11 | Ex. 12 | Ex. 13 | Ex. 14 | Ex. 15 | Ex. 16 | Ex. 17 | Ex. 18 | Ex. 3 | Ex. 4 |
| Copolymer | Syn. Ex. 1 | Parts | 100 | | | | | | | | | | |
| (A) or (cA) | Syn. Ex. 2 | by | | 100 | | | | | | | | | |
| | Syn. Ex. 3 | mass | | | 100 | | | | | | | | |
| | Syn. Ex. 4 | | | | | 100 | | | | | | | |
| | Syn. Ex. 5 | | | | | | 100 | | | | | | |
| | Syn. Ex. 6 | | | | | | | 100 | | | | | |
| | Syn. Ex. 7 | | | | | | | | 100 | | | | |
| | Syn. Ex. 8 | | | | | | | | | 100 | | | |
| | Syn. Ex. 9 | | | | | | | | | | 100 | | |
| | Comp. | | | | | | | | | | | 100 | |
| | Syn. Ex. 1 | | | | | | | | | | | | |
| | Comp. | | | | | | | | | | | | 100 |
| | Syn. Ex. 2 | | | | | | | | | | | | |

| Reactive diluent (B) | | 100 | 100 | 100 | 100 | 100 | 100 | 100 | 100 | 100 | 100 | 100 |
|---|---|---|---|---|---|---|---|---|---|---|---|---|
| Photopolymerization initiator (C) | | 5 | 5 | 5 | 5 | 5 | 5 | 5 | 5 | 5 | 5 | 5 |
| Solvent (D) | | 595 | 595 | 595 | 595 | 595 | 595 | 595 | 595 | 595 | 595 | 595 |
| Coloring agent (E) | | 50 | 50 | 50 | 50 | 50 | 50 | 50 | 50 | 50 | 50 | 50 |
| Solvent resistance | Residual | 92 | 91 | 90 | 90 | 85 | 86 | 89 | 85 | 88 | 85 | 85 |
| (100° C. 20 min) | film rate (%) | | | | | | | | | | | |
| Developability | Solubility | 2 | 2 | 1 | 1 | 1 | 2 | 1 | 2 | 2 | 3 | 3 |
| | Adhesion | 6 | 5 | 10 | 11 | 5 | 6 | 7 | 8 | 6 | 25 | 30 |
| | (μm) | | | | | | | | | | | |

### [Evaluation of Solvent Resistance]

Solvent resistance was evaluated by the residual film rate.

### (Residual Film Rate)

The photosensitive coloring compositions of Examples 10 to 18 and Comparative Examples 3 and 4 were each applied by spin coating onto a glass substrate (alkali-free glass substrate) having a square shape that was 5 cm in length and 5 cm in width in a plan view so that the thickness after exposure reached 2.5 μm to form a coating film. Next, the coating film was heated at 100° C. for 3 minutes, thereby removing the solvent (D) in the coating film by evaporation.

Next, the coating film was exposed by being irradiated with ultraviolet rays having a wavelength of 365 nm at an energy ray amount of 100 mJ/cm², and the exposed portion was photocured. Thereafter, a baking treatment was performed at 100° C. for 20 minutes to cure the coating film and form a cured film. The thickness of the prepared cured film was measured with a step gauge, and was denoted at this time as X.

Thereafter, the prepared cured film was immersed in 20 g of propylene glycol monomethyl ether acetate (PGMEA) at 23° C. for 15 minutes. The immersed coating film was dried at 40° C. in a vacuum for 30 minutes, and the thickness of the coating film was then measured with the step gauge. The thickness at this time was denoted as Y.

The rate of the thickness Y of the cured film after the PGMEA immersion to the thickness X of the cured film before the PGMEA immersion was calculated as the residual film rate by the following formula, and the solvent resistance of the cured film was evaluated. That is, the closer the residual film rate is to 100%, the better the solvent resistance of the cured film. As an evaluation, 80% or more of the residual film rate was determined as a pass line. The residual film rates of the cured films are shown in Table 2.

Residual film rate=(Y/X)×100(%)

As shown in Table 2, for the cured films of the resin compositions of Examples 10 to 18, the residual film rates (%) after the PGMEA immersion were 85% or more, and the solvent resistance was good even when the temperature of the baking treatment was a low temperature of 100° C.

[Evaluation of developability]

Developability was evaluated by the solubility and adhesion of the cured film.

### (Solubility)

The photosensitive coloring compositions prepared in Examples 10 to 18 and comparative examples 3 to 4 were each applied by spin coating onto a 5 cm square glass substrate (alkali-free glass substrate) so that the thickness after exposure reached 1.5 μm (coating step). The glass substrate coated with the photosensitive coloring composition was heated at 100° C. for 3 minutes to volatilize the solvent to dry the coating film (pre-baking step).

Next, the surface of the dried coating film was irradiated with 100 mJ/cm² of light using an ultra-high pressure mercury lamp through a photomask (exposure step). The exposure step was performed with the photomask installed at a position 100 μm away from the coating film. As the photomask, a mask having a line and space pattern that was 3 to 100 μm in width was used. Next, a semi-clean DL-A10 developing solution (manufactured by Yokohama Oils & Fats Industry Co., Ltd.) (diluted 300 times) was sprayed onto the surface of the coating film for 60 seconds under conditions of a temperature of 23° C. and a 0.1 MPa pressure, thereby removing the unexposed portion (development step). The dissolution form of the coating film at the time of spraying the developing solution was observed, and the solubility was evaluated by the following criteria. The results are shown in Table 2.
1: There is no residue in the unexposed portion, no powder is seen in the developing solution, and the pattern shape is good
2: Although there is no residue in the unexposed portion, a powder is seen in the developing solution, and the pattern shape is relatively good
3: A residue remains in the unexposed portion, and there is a place where the pattern shape is missing
4: The film peels off from the exposed portion, and no pattern remains

### (Adhesion)

The glass substrate having the coating film after the development step was left to stand in a dryer at 100° C. for 30 minutes, whereby the coating film was thermally cured (post baking step), and a coloring pattern was obtained. The coloring pattern thus obtained was observed using a microscope, and the adhesion was evaluated by the observable minimum line width (minimum development dimension (μm)). The results are shown in Table 2.

INDUSTRIAL AVAILABILITY

According to the present invention, a photosensitive resin composition that imparts a resin cured film having excellent solvent resistance is provided. In addition, according to the present invention, an image display element including a color filter having a coloring pattern comprising a resin cured film having excellent solvent resistance is provided. The photosensitive resin composition and the photosensitive coloring composition can be preferably used as a material for a transparent film, a protective film, an insulating film, an overcoat, a photo spacer, a black matrix, a black column spacer, a color filter resist, and the like.

1. A photosensitive coloring composition comprising:
a copolymer (A) comprising
a structural unit (a) having an acid group; and
a structural unit (b) having a group represented by the following formula (1-1) or the following formula (1-2): 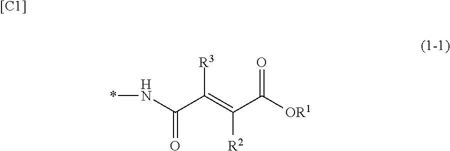
wherein, in formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group of formula (1-1) from the structural unit (b); 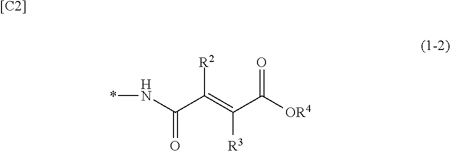
wherein, in formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group of formula (1-2) from the structural unit (b);
a reactive diluent (B);
a photopolymerization initiator (C);
a solvent (D); and
a coloring agent (E).

2. The photosensitive coloring composition according to claim 1, wherein the copolymer (A) further comprises
a structural unit (c) having a hydroxy group; and
a structural unit (d) having a blocked isocyanate group.

3. The photosensitive coloring composition according to claim 2, wherein a blocking agent of the structural unit (d) having a blocked isocyanate group is one or more selected from the group consisting of 3,5-dimethylpyrazole, methyl ethyl ketoxime, methyl 4-hydroxybenzoate, methyl 2-hydroxybenzoate, and 3,5-xylenol.

4. The photosensitive coloring composition according to claim 2, wherein the blocking agent of the structural unit (d) having a blocked isocyanate group has a carboxylic acid alkyl ester structure.

5. The photosensitive coloring composition according to claim 2, wherein the structural unit (d) having a blocked isocyanate group has a group represented by the following formula (2) or a group represented by the following formula (3): 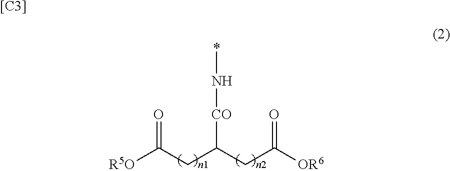
wherein, in formula (2), R⁵ and R⁶ each independently represent an alkyl group having 1 to 10 carbon atoms, n1 and n2 each independently represent an integer of 0 to 2, and * represents a linking site with a residue obtained by removing the blocked isocyanate group from the structural unit (d); 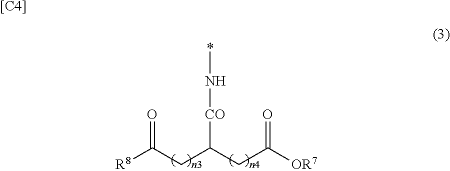
wherein, in formula (3), R⁷ and R⁸ each independently represent an alkyl group having 1 to 10 carbon atoms, n3 and n4 each independently represent an integer of 0 to 2, and * represents a linking site with a residue obtained by removing the blocked isocyanate group from the structural unit (d).

6. The photosensitive coloring composition according to claim 2, wherein the copolymer (A) further comprises a different structural unit (e) other than the structural units (a) to (d),
wherein the structural unit (e) is a structural unit derived from an alkyl (meth)acrylate in which the number of carbon atoms in an alkyl group is 1 to 12.

7. The photosensitive coloring composition according to claim 1, wherein an acid value of the copolymer (A) is 10 to 300 KOH mg/g.

8. The photosensitive coloring composition according to claim 1, wherein the copolymer (A) comprises 3 to 40 mol % of the structural unit (b).

9. The photosensitive coloring composition according to claim 1, wherein a weight average molecular weight of the copolymer (A) is 1000 to 50000, and
an ethylenically unsaturated group equivalent of the copolymer (A) is 300 to 8000 g/mol.

10. (canceled)

11. The photosensitive resin composition according to claim 1, comprising:
10 parts by mass to 90 parts by mass of the copolymer (A),
10 parts by mass to 90 parts by mass of the reactive diluent (B),
0.1 parts by mass to 30 parts by mass of the photopolymerization initiator (C), and
30 parts by mass to 1,000 parts by mass of the solvent (D), based on 100 parts by mass of the total of the copolymer (A) and the reactive diluent (B).

12. (canceled)

13. The photosensitive coloring composition according to claim 1, comprising:
10 parts by mass to 90 parts by mass of the copolymer (A),
10 parts by mass to 90 parts by mass of the reactive diluent (B),
0.1 parts by mass to 30 parts by mass of the photopolymerization initiator (C),
30 parts by mass to 1,000 parts by mass of the solvent (D), and
3 parts by mass to 80 parts by mass of the coloring agent (E), based on 100 parts by mass of the total of the copolymer (A) and the reactive diluent (B).

14. (canceled)

15. A resin cured film comprising a cured product of the photosensitive coloring composition according to claim 1.

16. A color filter comprising a coloring pattern comprising a cured product of the photosensitive coloring composition according to claim 1.

17. An image display element comprising the color filter according to claim 16.
